(19) United States
(12) Patent Application Publication
(10) Pub. No.: US 2024/0224647 A1
(43) Pub. Date: Jul. 4, 2024

(54) LIGHT EMITTING DISPLAY DEVICE

(71) Applicant: LG DISPLAY CO., LTD., Seoul (KR)

(72) Inventors: Booheung LEE, Gimpo-si (KR); DaHye SHIM, Seoul (KR); KiSeob SHIN, Goyang-si (KR)

(73) Assignee: LG DISPLAY CO., LTD., Seoul (KR)

(21) Appl. No.: 18/381,033

(22) Filed: Oct. 17, 2023

(30) Foreign Application Priority Data
Dec. 29, 2022 (KR) 10-2022-0189032

(51) Int. Cl. H10K 59/131; G09G 3/3233; H10K 59/35; H10K 59/80

(52) U.S. Cl. CPC H10K 59/131; G09G 3/3233; H10K 59/35; H10K 59/879; G09G 2320/068

(57) ABSTRACT

A light-emitting display device can include a display panel in which an active area including a first active area and a second active area, and a non-active area adjacent to the active area are defined. Also, the light-emitting display device can include a plurality of sub-pixels disposed in the active area, and a gate driver disposed on the non-active area. Each of the plurality of sub-pixels can include a first light-emitting diode (LED) that emits light in response to a driving current and a first lens that refracts the light emitted from the first LED. Also, the light-emitting display device can operate in different modes that have different viewing angles by using the lens to limit or control a viewing angle in each of the first and second active areas and the display panel can selectively change the viewing angle on demand.

### CROSS-REFERENCE TO RELATED APPLICATIONS

This application claims the priority benefit under 35 U.S.C. § 119(a) to Korean Patent Application No. 10-2022-0189032, filed in the Republic of Korean on Dec. 29, 2022, the entire disclosure of which is incorporated herein by reference.

### BACKGROUND

### Field of the Invention

The present disclosure relates to a light-emitting display device, and more particularly, to a light-emitting display device whose viewing angle can be selectively controlled.

### Discussion of the Related Art

An organic light-emitting diode (OLED) is a self-emitting element that includes an anode electrode, a cathode electrode and an organic compound layer formed between the anode electrode and the cathode electrode. The organic compound layer includes a hole transport layer (HTL), an emission layer (EML) and an electron transport layer (ETL). When a driving voltage is applied to the anode electrode and the cathode electrode, holes passing through the HTL and electrons passing through the ETL move to the EML and form excitons. As a result, the EML generates visible light. An active matrix light-emitting display device includes an organic light emitting diode (OLED) capable of emitting light by itself, and has great advantages of fast response time, high emission efficiency, high luminance and wide viewing angle. Thus, the active matrix light-emitting display device has been used in various fields.

In the light-emitting display device, pixels each including an OLED are arranged in a matrix form and the luminance of the pixels is adjusted depending on a gray scale of video data.

As described above, the light-emitting display device is not limited in viewing angle (e.g., it has a wide viewing angle), but it has recently been desirable to have a limited viewing angle for privacy protection and information protection. For example, when checking one's bank account or viewing other private information while in a public space, or when different users are using a same display device but have different needs.

Also, when the light-emitting display device is used to provide driving information in a vehicle, an image displayed by the light-emitting display device may be reflected from a window of the vehicle and thus may block a driver's view or distract the driver. Such a reflection of the image in the vehicle is particularly severe while driving at night and can adversely affect the driver's safe driving. Therefore, it is desirable for a light-emitting display device in a vehicle to have a limited viewing angle or a selectable viewing angle.

Meanwhile, such limitation of control of the viewing angle varies depending on whether a vehicle is currently being driven and whether a driver and a passenger are viewing the light-emitting display device at the same time while the vehicle is stationary (e.g., watching a movie or TV show while the vehicle is parked). Therefore, it desirable to be able to selectively switch the viewing angle on demand.

Also, in some countries, exposure of multimedia played back in front of a passenger seat to a driver is prohibited or against the law. Therefore, there is a need for a display device that has a viewing angle needs that can be selectively switched on demand.

### SUMMARY OF THE DISCLOSURE

An object to be achieved by the present disclosure is to provide a light-emitting display device in which each of a plurality of active areas of a display panel can selectively limit a viewing angle.

Another object to be achieved by the present disclosure is to provide a light-emitting display device in which each of a plurality of active areas can operate independently in a private viewing mode or a share viewing mode.

Yet another object to be achieved by the present disclosure is to provide a light-emitting display device with a reduced bezel.

Still another object to be achieved by the present disclosure is to provide a light-emitting display device in which a delay occurring during a transfer of a signal output from a gate driver to a signal line can be suppressed.

Objects of the present disclosure are not limited to the above-mentioned objects, and other objects, which are not mentioned above, can be clearly understood by those skilled in the art from the following descriptions.

According to an aspect of the present disclosure, the light-emitting display device includes a display panel in which an active area including a first active area and a second active area, and a non-active area adjacent to the active area are defined. Also, the light-emitting display device includes a plurality of sub-pixels disposed in the active area, and a gate driver disposed on the non-active area. Each of the plurality of sub-pixels includes a first light-emitting diode (LED) that emits light in response to a driving current and a first lens that refracts the light emitted from the first LED. Therefore, according to the present disclosure, the light-emitting display device can operate in different viewing modes by using the lens to limit or control a viewing angle in each of the first and second active areas.

According to another aspect of the present disclosure, the light-emitting display device includes a display panel in which an active area including a first active area and a second active area, and a non-active area adjacent to the active area are defined. Also, the light-emitting display device includes a plurality of sub-pixels disposed in the active area, and a plurality of emission signal lines that extend in one direction in the active area and apply an emission signal to the plurality of sub-pixels. At least some of the plurality of emission signal lines are separated at the boundary between the first active area and the second active area. Therefore, according to the present disclosure, it is possible to independently control each active area by separating the emission signal lines in the first active area from the emission signal lines in the second active area.

Other detailed matters of the example embodiments are included in the detailed description and the drawings.

According to the present disclosure, each of a plurality of active areas can operate independently in a private viewing mode or a share viewing mode.

According to the present disclosure, a viewing angle can be selectively limited or controlled in each of the plurality of active areas.

According to the present disclosure, a delay occurring during a transfer of a signal output from a gate driver to a signal line can be suppressed.

According to the present disclosure, all the gate drivers are disposed in one part of a bezel, and, thus, the other part of the bezel can be minimized.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic plan view of a light-emitting display device according to an example embodiment of the present disclosure;

FIG. 2 is a schematic cross-sectional view of the light-emitting display device according to an example embodiment of the present disclosure;

FIG. 3 is a schematic cross-sectional view of a display panel of the light-emitting display device according to an example embodiment of the present disclosure;

FIG. 4A is a schematic drawing illustrating a first lens of the light-emitting display device according to an example embodiment of the present disclosure;

FIG. 4B is a schematic drawing illustrating a second lens of the light-emitting display device according to an example embodiment of the present disclosure;

FIG. 5A is a drawing illustrating an optical profile for a viewing angle of the first lens of the light-emitting display device according to an example embodiment of the present disclosure;

FIG. 5B is a drawing illustrating an optical profile for a viewing angle of the second lens of the light-emitting display device according to an example embodiment of the present disclosure;

FIG. 6 is a schematic drawing illustrating a share viewing mode operation and a private viewing mode operation of the light-emitting display device according to an example embodiment of the present disclosure;

FIG. 7 is a circuit diagram of a sub-pixel of the light-emitting display device according to an example embodiment of the present disclosure;

FIG. 8 is a waveform chart showing emission signals and scan signals in each of the share viewing mode and the private viewing mode of the light-emitting display device according to an example embodiment of the present disclosure;

FIG. 9 is a schematic enlarged plan view of the display panel of the light-emitting display device according to an example embodiment of the present disclosure;

FIG. 10 is a schematic enlarged plan view of the display panel operating in the share viewing mode and the private viewing mode according to an example embodiment of the present disclosure;

FIG. 11 is a circuit diagram of a first sub-pixel of a light-emitting display device according to another example embodiment of the present disclosure;

FIG. 12 is a waveform chart showing emission signals and scan signals of the light-emitting display device according to another example embodiment of the present disclosure;

FIG. 13 is a circuit diagram of a second sub-pixel of the light-emitting display device according to another example embodiment of the present disclosure;

FIG. 14 is a waveform chart showing emission signals and scan signals in each of the share viewing mode and the private viewing mode of the light-emitting display device according to another example embodiment of the present disclosure; and

FIG. 15 is a schematic enlarged plan view of a display panel of the light-emitting display device according to another example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only.” Any references to singular can include plural unless expressly stated otherwise.

Components are interpreted to include an ordinary error range even if not expressly stated.

When the position relation between two parts is described using the terms such as “on,” “above,” “below,” and “next,” one or more parts can be positioned between the two parts unless the terms are used with the term “immediately” or “directly.”

When an element or layer is disposed “on” another element or layer, another layer or another element can be interposed directly on the other element or therebetween.

Although the terms “first,” “second,” and the like are used for describing various components, these components are not confined by these terms. These terms are merely used for distinguishing one component from the other components. Therefore, a first component to be mentioned below can be a second component in a technical concept of the present disclosure. Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a light-emitting display device according to example embodiments of the present disclosure will be described in detail with reference to accompanying drawings.

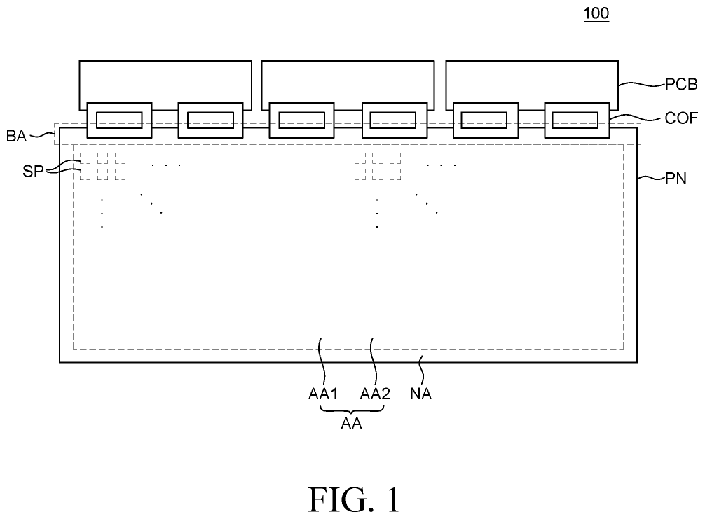

FIG. 1 is a schematic plan view of a light-emitting display device according to an example embodiment of the present disclosure. For the convenience of description, FIG. 1 illustrates only a display panel PN, a plurality of flexible films COF and a plurality of printed circuit boards PCB among various components of a light-emitting display device 100. All components of each light emitting display device according to all embodiments of the present disclosure are operatively coupled and configured.

Referring to FIG. 1, the light-emitting display device 100 according to an example embodiment of the present disclosure includes the display panel PN, the plurality of flexible films COF and the plurality of printed circuit boards PCB.

The display panel PN is configured to display an image to a user. An LED for displaying an image, a pixel circuit for driving the LED, a signal line for transferring various signals to the LED and the pixel circuit, and the like can be disposed in the display panel PN.

The display panel PN includes an active area AA and a non-active area NA.

The active area AA is an area that displays an image in the display panel PN. A plurality of sub-pixels SP constituting a plurality of pixels and a circuit for driving the plurality of sub-pixels SP can be disposed in the active area AA. The plurality of sub-pixels SP is a minimum unit constituting the active area AA (e.g., one pixel unit can be made up of six sub-pixels, but is not limited thereto). A plurality of scan signal lines SL and a plurality of data lines intersect each other in the plurality of sub-pixels SP. Each of the plurality of sub-pixels SP can be connected to a scan signal line SL and a data line.

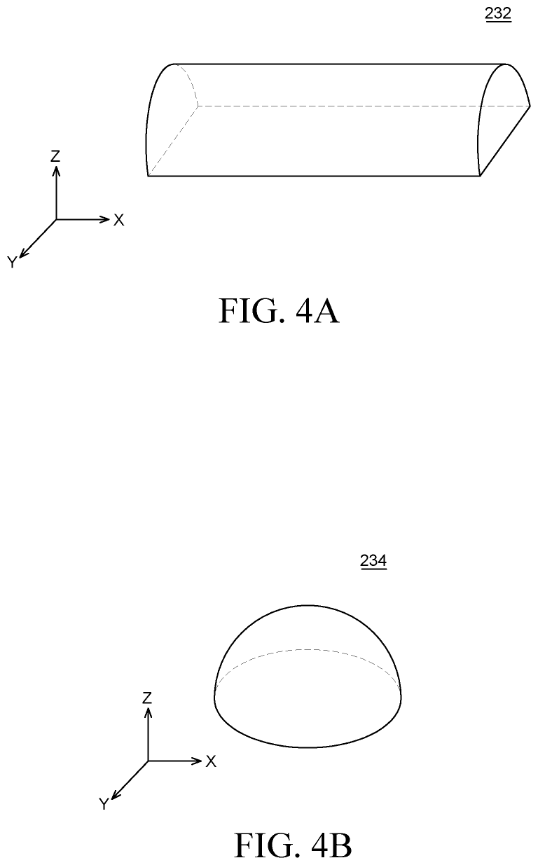

The active area AA includes a first active area AA1 and a second active area AA2. The first active area AA1 and the second active area AA2 operate independently of each other. Each of the first active area AA1 and the second active area AA2 can operate in any one of a share viewing mode and a private viewing mode in left and right directions. The first active area AA1 and the second active area AA2 can operate in the same mode or in different modes. In the private viewing mode, a viewing angle is narrow and limited in the left and right directions, and, thus, only some of a plurality of viewers can view an image. In the share viewing mode, the viewing angle is wide in the left and right directions, and, thus, more viewers can view the image. The private viewing mode and the share viewing mode will be described in more detail with reference to FIGS. 4A to 6.

Meanwhile, FIG. 1 illustrates that the active area AA includes the two active areas, e.g., the first active area AA1 and the second active area AA2. However, the active area AA can also include three or more active areas AA which operate independently, but is not limited thereto.

The non-active area NA is an area that does not display an image. Various signal lines and circuits for driving the LED in the active area AA are disposed in the non-active area NA. For example, link lines for transferring a signal to the plurality of sub-pixels SP and circuits in the active area AA can be disposed in the non-active area NA, but the present disclosure is not limited thereto.

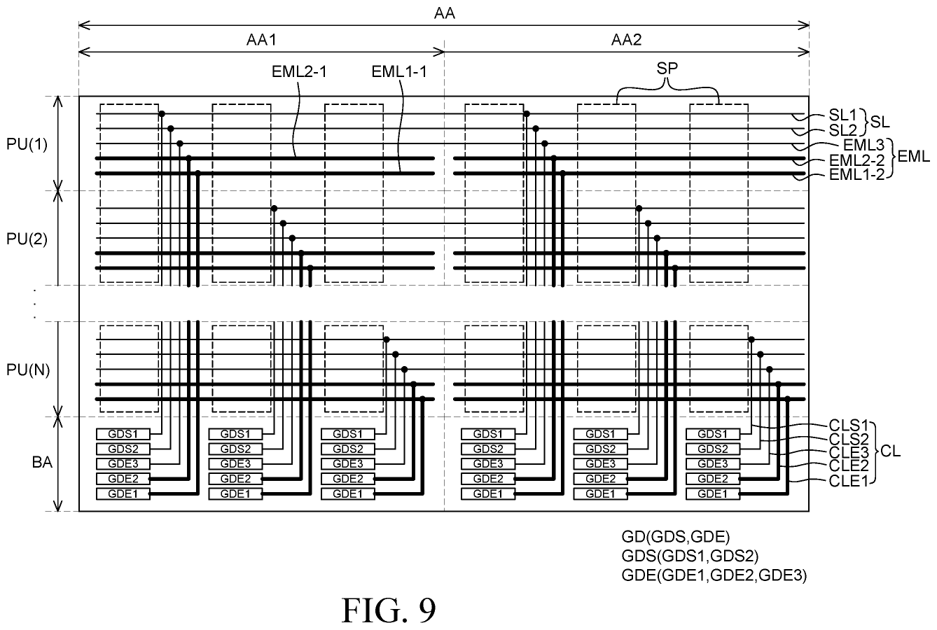

A gate driver GD is disposed in the display panel PN. For example, the gate driver GD (see FIG. 9 and below) can be disposed on a part of the non-active area NA where the plurality of flexible films COF are bonded in the display panel PN. Hereinafter, for the convenience of description, the part of the non-active area NA on which the gate driver GD is mounted will be referred to as a bezel area BA. As such, the light-emitting display device 100 according to an example embodiment of the present disclosure will be described.

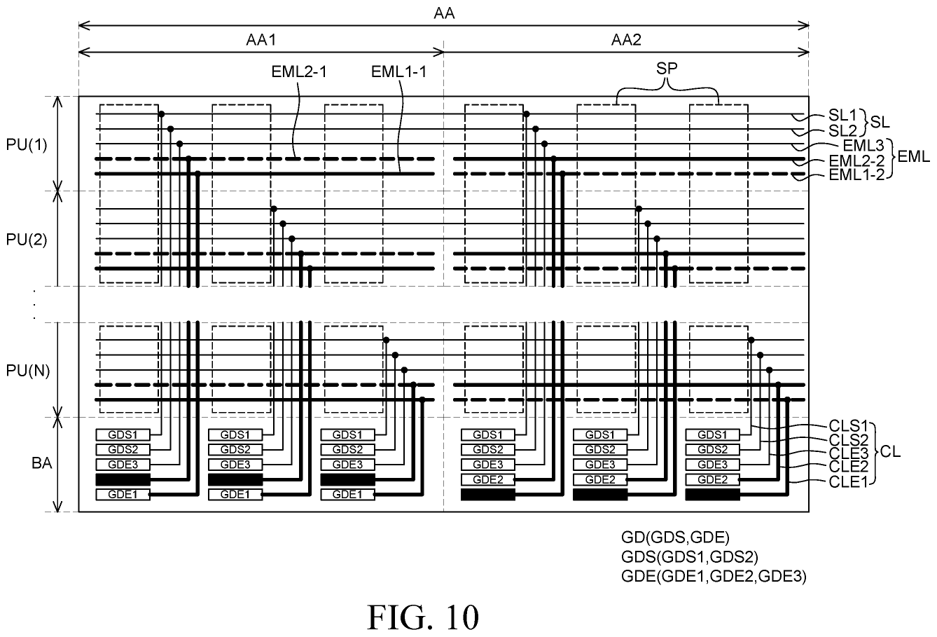

In the light-emitting display device 100 according to an example embodiment of the present disclosure, the gate driver GD is disposed only in the bezel area BA. Thus, the size of the non-active area NA except the bezel area BA can be minimized. Also, a scan line and an emission signal line EML (see FIG. 9 and below) connected to the gate driver GD are separated for each active area AA. Thus, the first active area AA1 and the second active area AA2 can operate independently in the share viewing mode or the private viewing mode. For example, the first active area AA1 can operate in the share viewing mode while the second active area AA2 operates in the private viewing mode, and vice versa. Of course, the first active area AA1 and the second active area AA2 can also operate in the same viewing mode at the same time. The gate driver GD will be described later in more detail with reference to FIGS. 9 and 10.

At least one flexible film COF is disposed at one end of the display panel PN. The plurality of flexible films COF can be electrically connected to the non-active area NA of the display panel PN. Each of the plurality of flexible films COF is a film in which various components are disposed as a base film having malleability. The plurality of flexible films COF supply signals to the plurality of sub-pixels SP and driving circuits in the active area AA. Also, the plurality of flexible films COF can be electrically connected to the display panel PN. For example, the plurality of flexible films COF can supply a power voltage or a data voltage Vdata to the plurality of sub-pixels SP and the driving circuits in the active area AA.

Meanwhile, a driving integrated circuit (IC) such as a data driver IC can be disposed in the plurality of flexible films COF. The driving IC is configured to process data for displaying an image and a driving signal for processing the data. The driving IC can be implemented by a chip on glass (COG), a chip on film (COF), or a tape carrier package (TCP) technique depending on a mounting method. However, for the convenience of description, the driving IC is described, for example, as being disposed on the plurality of flexible films COF by the chip on film technique, but is not limited thereto. The driving IC can also be disposed as a single chip integrated with a timing controller.

Each of the plurality of printed circuit boards PCB is electrically connected to one or more of the plurality of flexible films COF. The plurality of printed circuit boards PCB are configured to supply a signal to the driving IC. Various components for supplying various signals, such as a driving signal and a data signal, to the driving IC can be disposed in the plurality of printed circuit boards PCB.

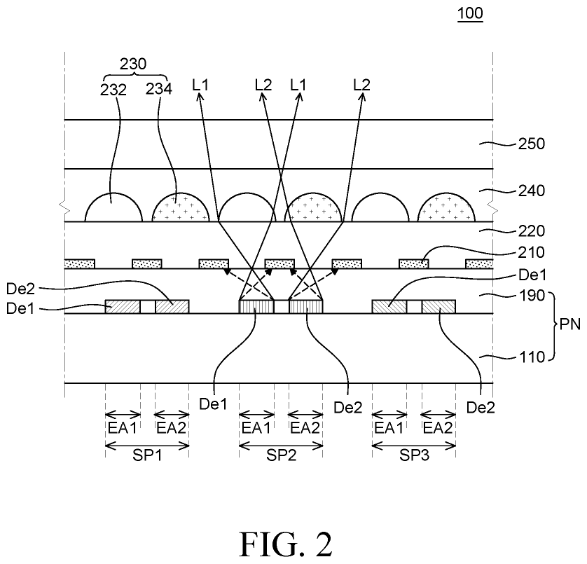

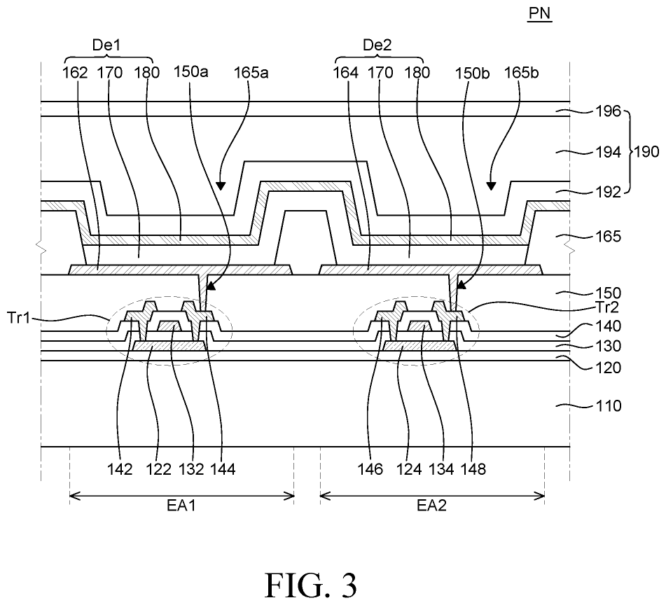

Hereinafter, the display panel of the light-emitting display device 100 according to an example embodiment of the present disclosure will be described with reference to FIGS. 2 to 3.

FIG. 2 is a schematic cross-sectional view of the light-emitting display device according to an example embodiment of the present disclosure. FIG. 3 is a schematic cross-sectional view of a display panel of the light-emitting display device according to an example embodiment of the present disclosure.

Referring to FIG. 2, the light-emitting display device 100 according to an example embodiment of the present disclosure includes the display panel PN, a light blocking pattern 210 and an optical gap layer 220. Also, the light-emitting display device 100 according to an example embodiment of the present disclosure includes a lens layer 230, a planarization film 240 and a polarization layer 250.

Referring to FIGS. 2 and 3 together, the display panel PN includes a substrate 110, a plurality of first LEDs De1, a plurality of second LEDs De2 and a sealing layer 190.

The plurality of sub-pixels SP including first to third sub-pixels SP1, SP2 and SP3 are defined on the substrate 110. Further, each of the first to third sub-pixels SP1, SP2 and SP3 includes a first emission area EA1 and a second emission area EA2. In other words, each sup-pixel can have two separate light emitting elements.

A first LED De1 is provided in the first emission area EA1, and a second LED De2 is provided in the second emission area EA2.

The first to third sub-pixels SP1, SP2 and SP3 can be a red sub-pixel, a green sub-pixel and a blue sub-pixel, respectively. Therefore, the first LED De1 and the second LED De2 of the first sub-pixel SP1 can emit red light, and the first LED De1 and the second LED De2 of the second sub-pixel SP2 can emit green light. Also, the first LED De1 and the second LED De2 of the third sub-pixel SP3 can emit blue light.

Referring to FIGS. 2 and 3, the display panel PN of the light-emitting display device 100 according to an example embodiment of the present disclosure includes the substrate 110 and a plurality of thin film transistors Tr1 and Tr2. Also, the display panel PN of the light-emitting display device 100 according to an example embodiment of the present disclosure includes a plurality of LEDs De1 and De2 and the sealing layer 190.

Specifically, each sub-pixel SP on the substrate 110 includes the first emission area EA1 and the second emission area EA2. The substrate 110 can be a glass substrate or a plastic substrate.

For example, the plastic substrate can be made of polyimide (PI), but is not limited thereto.

A buffer layer 120 can be formed on the substrate 110. The buffer layer 120 is substantially positioned on the entire surface of the substrate 110. The buffer layer 120 can be made of an inorganic material such as silicon oxide (SiO₂) or silicon nitride (SiNₓ), and can be configured by a single layer or multiple layers.

A first semiconductor layer 122 and a second semiconductor layer 124 are patterned in the first emission area EA1 and the second emission area EA2, respectively, on the buffer layer 120.

Each of the first semiconductor layer 122 and the second semiconductor layer 124 can be made of an oxide semiconductor material. In this situation, a shield pattern can be further formed under the first semiconductor layer 122 and the second semiconductor layer 124. The shield pattern blocks light incident onto the first semiconductor layer 122 and the second semiconductor layer 124 and thus suppresses thermal degradation of the first semiconductor layer 122 and the second semiconductor layer 124.

Alternatively, each of the first semiconductor layer 122 and the second semiconductor layer 124 can be made of polycrystalline silicon. In this situation, both edges of each of the first semiconductor layer 122 and the second semiconductor layer 124 can be doped with impurities.

A gate insulating film 130 made of an insulating material is formed on the first semiconductor layer 122 and the second semiconductor layer 124 substantially over the entire surface of the substrate 110. The gate insulating film 130 can be made of an inorganic insulating material such as silicon oxide (SiO₂) or silicon nitride (SiNₓ).

The first semiconductor layer 122 and the second semiconductor layer 124 can be made of an oxide semiconductor material, and the gate insulating film 130 can be made of silicon oxide (SiO₂). Also, the first semiconductor layer 122 and the second semiconductor layer 124 can be made of polycrystalline silicon, and the gate insulating film 130 can be made of silicon oxide (SiO₂) or silicon nitride (SiNₓ).

A first gate electrode 132 and a second gate electrode 134 made of a conductive material such as metal are formed on the gate insulating film 130 corresponding to the first semiconductor layer 122 and the second semiconductor layer 124, respectively. Also, a scan signal line can be formed on the gate insulating film 130. The scan signal line SL can extend along one direction.

Meanwhile, the gate insulating film 130 is formed on the entire surface of the substrate 110 according to an example embodiment of the present disclosure. However, the gate insulating film 130 can be patterned to have the same shape as the first gate electrode 132 and the second gate electrode 134, and disposed only under the first gate electrode 132 and the second gate electrode 134.

An interlayer insulating film 140 made of an insulating material is formed on the first gate electrode 132 and the second gate electrode 134 substantially over the entire surface of the substrate 110. The interlayer insulating film 140 can be made of an inorganic insulating material such as silicon oxide (SiO₂) or silicon nitride (SiNₓ), or can be made of an organic insulating material such as photo acryl or benzocyclobutene.

The interlayer insulating film 140 includes contact holes that expose upper surfaces of both sides of the first semiconductor layer 122 and the second semiconductor layer 124. The contact holes can also be formed in the gate insulating film 130. A first source electrode 142 and a first drain electrode 144, and a second source electrode 146 and a second drain electrode 148 made of a conductive material such as metal are formed in the first emission area EA1 and the second emission area EA2, respectively, on the interlayer insulating film 140. Also, a data line and a power line extending along a direction perpendicular to the one direction can be formed on the interlayer insulating film 140.

The first source electrode 142 and the first drain electrode 144 are in contact with both sides of the first semiconductor layer 122 through the contact holes of the interlayer insulating film 140. The second source electrode 146 and the second drain electrode 148 are in contact with both sides of the second semiconductor layer 124 through the contact holes of the interlayer insulating film 140. Also, the data line extends along the direction perpendicular to the one direction and intersects the scan signal line SL to define a pixel area corresponding to each sub-pixel SP. Also, the power line that supplies a high-potential voltage is spaced apart from the data line.

Meanwhile, the first semiconductor layer 122, the first gate electrode 132, the first source electrode 142 and the first drain electrode 144 constitute a first thin film transistor Tr1. Also, the second semiconductor layer 124, the second gate electrode 134, the second source electrode 146 and the second drain electrode 148 constitute a second thin film transistor Tr2.

At least one thin film transistor having the same structure as the first thin film transistor Tr1 and the second thin film transistor Tr2 can be further formed on the substrate 110 of each sub-pixel SP. However, the present disclosure is not limited thereto.

A protective film 150 made of an insulating material is formed on the first source electrode 142, the first drain electrode 144, the second source electrode 146 and the second drain electrode 148 substantially over the entire surface of the substrate 110. The protective film 150 can be made of an organic insulating material such as photo acryl or benzocyclobutene. The protective film 150 has a flat upper surface. For example, the protective film 150 can also perform a planarization function.

Meanwhile, an insulating film made of an inorganic insulating material such as silicon oxide (SiO₂) or silicon nitride (SiNₓ) can be further formed under the protective film 150. Also, the insulating film can be further formed between the first and second thin film transistors Tr1 and Tr2 and the protective film 150.

The protective film 150 includes a first drain contact hole 150a and a second drain contact hole 150b that expose the first drain electrode 144 and the second drain electrode 148, respectively.

A first anode electrode 162 and a second anode electrode 164 made of a conductive material having a relatively high work function are formed on the protective film 150. The first anode electrode 162 is positioned in the first emission area EA1 and is in contact with the first drain electrode 144 through the first drain contact hole 150a. Also, the second anode electrode 164 is positioned in the second emission area EA2 and is in contact with the second drain electrode 148 through the second drain contact hole 150b.

For example, each of the first anode electrode 162 and the second anode electrode 164 can be made of a transparent conductive material such as indium tin oxide (ITO) or indium zinc oxide (IZO), but is not limited thereto.

Meanwhile, the display panel PN of the light-emitting display device 100 according to an example embodiment of the present disclosure can a top emission type of display device where light emitted from a plurality of LEDs is output toward an upper side of the substrate 110. Accordingly, each of the first anode electrode 162 and the second anode electrode 164 can further include a reflective electrode or reflective layer made of a metal material having high reflectivity under the transparent conductive material. For example, the reflective electrode or reflective layer can be made of an aluminum-palladium-copper (APC) alloy, silver (Ag) or aluminum (Al). In this situation, each of the first anode electrode 162 and the second anode electrode 164 can have a triple-layer structure of ITO/APC/ITO, ITO/Ag/ITO or ITO/AI/ITO, but is not limited thereto.

A bank 165 made of an insulating material is formed on the first anode electrode 162 and the second anode electrode 164. The bank 165 overlaps edges of the first anode electrode 162 and the second anode electrode 164, and covers the edges of the first anode electrode 162 and the second anode electrode 164. The bank 165 includes a first opening 165a and a second opening 165b that expose the first anode electrode 162 and the second anode electrode 164, respectively.

At least an upper surface of the bank 165 is hydrophobic, and side surfaces of the bank 165 can be hydrophobic or hydrophilic. The bank 165 can be made of an organic insulating material having hydrophobic properties. Alternatively, the bank 165 can be made of an organic insulating material having hydrophilic properties and subjected to a hydrophobic treatment.

The bank 165 has a single-layer structure in the present disclosure, but can have a double-layer structure or two or more layers. Also, the bank 165 can have a double-layer structure including a lower bank 165 which is hydrophilic and an upper bank 165 which is hydrophobic.

Then, an emission layer 170 is formed on the first anode electrode 162 and the second anode electrode 164 exposed through the first opening 165a and the second opening 165b of the bank 165. The emission layer 170 on the first anode electrode 162 and the emission layer 170 on the second anode electrode 164 are connected to each other as one body. However, the present disclosure is not limited thereto. Alternatively, the emission layer 170 on the first anode electrode 162 and the emission layer 170 on the second anode electrode 164 can be separated from each other.

Also, the emission layer 170 can include a first charge auxiliary layer, a light-emitting material layer and a second charge auxiliary layer sequentially positioned on the first anode electrode 162 and the second anode electrode 164. The light-emitting material layer can be made of any one of red, green and blue light-emitting materials, but is not limited thereto. The light-emitting materials can be organic light-emitting materials such as phosphorescent compounds or fluorescent compounds. However, the present disclosure is not limited thereto. An inorganic light-emitting material such as a quantum dot can also be used.

The first charge auxiliary layer can be a hole auxiliary layer, and the hole auxiliary layer can include at least one of a hole injection layer (HIL) and a hole transport layer (HTL). Also, the second charge auxiliary layer can be an electron auxiliary layer, and the electron auxiliary layer can include at least one of an electron injection layer (EIL) and an electron transport layer (ETL).

The emission layer 170 can be formed by an evaporation process. In this situation, a fine metal mask (FMM) can be used for patterning the emission layer 170 in each sub-pixel SP. Alternatively, the emission layer 170 can be formed by a solution process. In this situation, the emission layer 170 can be provided only in the first opening 165a and the second opening 165b. Also, the emission layer 170 adjacent to the bank 165 can have a greater height as it gets closer to the bank 165.

A cathode electrode 180 made of a conductive material having a relatively low work function is formed on the emission layer 170 substantially over the entire surface of the substrate 110. Herein, the cathode electrode 180 can be made of aluminum, magnesium, silver or an alloy thereof. In this situation, the cathode electrode 180 has a relatively small thickness to transmit light emitted from the emission layer 170.

Alternatively, the cathode electrode 180 can be made of a transparent conductive material such as indium gallium oxide (IGO), but is not limited thereto.

The first anode electrode 162, the emission layer 170 and the cathode electrode 180 in the first emission area EA1 constitute the first LED De1. Also, the second anode electrode 164, the emission layer 170 and the cathode electrode 180 in the second emission area EA2 constitute the second LED De2.

As described above, the display panel PN according to an example embodiment of the present disclosure can be of the top emission type where light emitted from the emission layer 170 of the first LED De1 and the second LED De2 is output in a direction opposite to the substrate 110, e.g., to the outside through the cathode electrode 180. The top emission display type can have a greater emission area than a bottom emission display type having the same size, and thus can have improved luminance and reduced power consumption.

The sealing layer 190 having a flat upper surface is formed on the cathode electrode 180 substantially over the entire surface of the substrate 110. The sealing layer 190 suppresses introduction of moisture or oxygen from the outside into the first LED De1 and the second LED De2. Therefore, the sealing layer 190 can also be referred to as an encapsulation layer. Also, the sealing layer 190 can perform a planarization function.

The sealing layer 190 can have a laminated structure including a first inorganic film 192, an organic film 194 and a second inorganic film 196. Herein, the organic film 194 can serve to cover foreign matters generated during a manufacturing process.

Referring back to FIG. 2, the light blocking pattern 210 is provided on the display panel PN, specifically, on the sealing layer 190. The light blocking pattern 210 can be formed between the first to third sub-pixels SP1, SP2 and SP3 adjacent to each other, or can be formed between the first emission area EA1 and the second emission area EA2.

The light blocking pattern 210 can be a black matrix, and can be made of black resin or chromium oxide. Alternatively, the light blocking pattern 210 can be a touch electrode, and can be made of metal. In this situation, the touch electrode includes a plurality of transmission electrodes and a plurality of reception electrodes intersecting each other. The touch electrode can sense a touch based on a variance in capacitance between the plurality of transmission electrodes and the plurality of reception electrodes.

The optical gap layer 220 is provided on the light blocking pattern 210. The optical gap layer 220 secures an optical gap between the first and second LEDs De1 and De2 and lenses 232 and 234 of the lens layer 230 to allow light emitted from the first LED De1 and the second LED De2 to be refracted by the lenses 232 and 234 in a specific direction. Thus, the optical gap layer 220 improves the efficiency of the lenses 232 and 234. The optical gap layer 220 can have a thickness of several to several tens of μm, and can be made of an organic insulating material.

For example, the optical gap layer 220 can be made of photo acryl, benzocyclobutene (BCB), polyimide (PI) or polyamide (PA), but is not limited thereto.

The lens layer 230 is provided on the optical gap layer 220. The lens layer 230 includes a first lens 232 and a second lens 234. The first lens 232 is disposed in the first emission area EA1 to refract light emitted from the first LED De1 in a specific direction. Also, the second lens 234 is disposed in the second emission area EA2 to refract light emitted from the second LED De2 in a specific direction. A part of each of the first lens 232 and the second lens 234 can overlap the light blocking pattern 210 but is not limited thereto.

The first lens 232 is a half-cylindrical lens, and the second lens 234 is a half-spherical lens. Thus, first light L1 emitted from the first LED De1 of each sub-pixel SP is refracted at a specific angle by the first lens 232 and then output. Also, second light L2 emitted from the second LED De2 of each sub-pixel SP is refracted at a specific angle by the second lens 234 and then output. Accordingly, it is possible to limit and selecting control a viewing angle of each sub-pixel SP.

The planarization film 240 is provided on the lens layer 230 to protect the first lens 232 and the second lens 234. The planarization film 240 is made of an organic insulating material and has a flat upper surface. Also, the planarization film 240 has a lower refractive index than a refractive index of the first lens 232 and a refractive index of the second lens 234.

For example, the planarization film 240 can be made of photo acryl, benzocyclobutene (BCB), polyimide (PI) or polyamide (PA), but is not limited thereto.

The polarization layer 250 is provided on the planarization film 240. The polarization layer 250 can include a linear polarization layer and a retardation layer. Also, the polarization layer 250 serves to change a polarization state of external light incident onto the display panel PN, and suppress re-emission of external light reflected from the display panel PN to the outside.

Meanwhile, in the light-emitting display device 100 according to an example embodiment of the present disclosure, each sub-pixel SP includes the first emission area EA1 and the second emission area EA2. Also, the first lens 232 having a half-cylindrical shape is provided in an upper part of the first emission area EA1, and the second lens 234 having a half-spherical shape is provided in an upper part of the second emission area EA2 to limit a viewing angle. Therefore, it is possible to implement the share viewing mode and the private viewing mode.

FIG. 4A schematically illustrates a first lens of the light-emitting display device according to an example embodiment of the present disclosure. FIG. 4B schematically illustrates a second lens of the light-emitting display device according to an example embodiment of the present disclosure.

Referring to FIG. 4A, the first lens 232 is a half-cylindrical lens having a rectangular cross-section in an X-axis direction and a semicircular cross-section in a Y-axis direction. Therefore, the first lens 232 limits a viewing angle in the Y-axis direction, but does not limit the viewing angle in a longitudinal direction of the second lens first lens 232, e.g., in the X-axis direction. For example, viewers positioned to the left and right sides could view the image.

Referring to FIG. 4B, the second lens 234 is a half-spherical lens having a semicircular cross-section in the X- and Y-axis directions. Therefore, the second lens 234 limits the viewing angle in the X- and Y-axis directions. For example, a viewer facing straight on could view the image, but viewers positioned to the left and right sides would have limited or impaired viewing angles and can be prevented from seeing the displayed image.

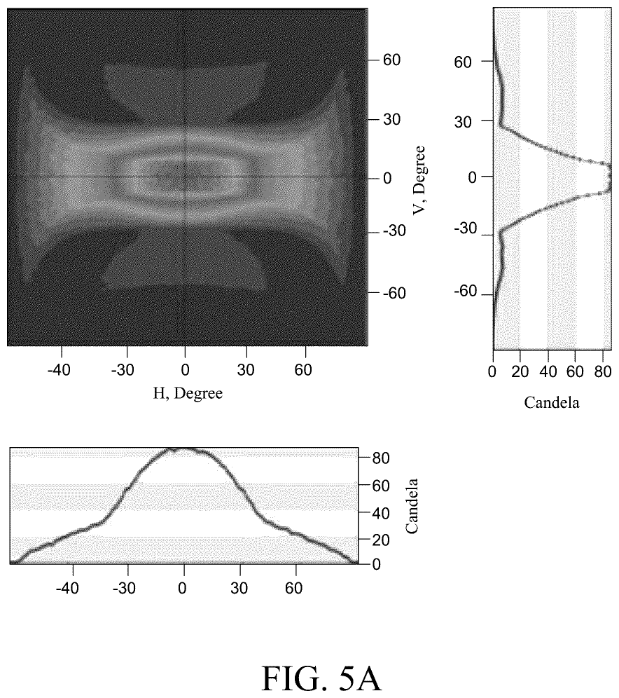

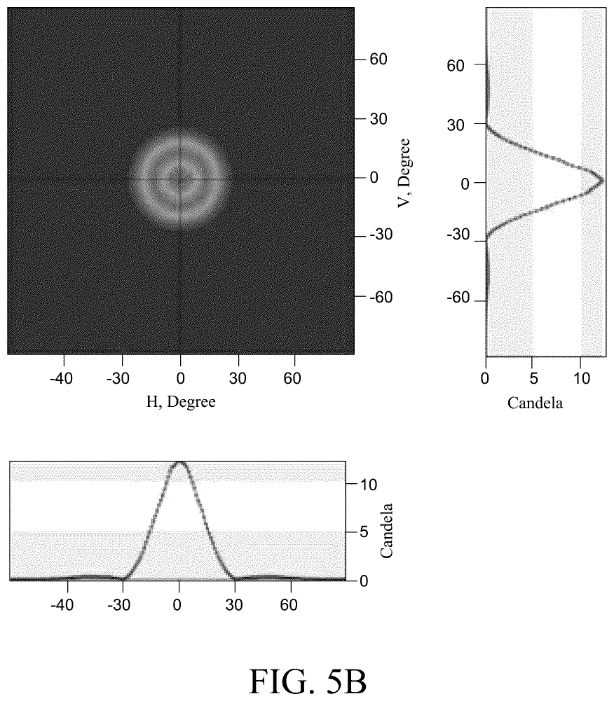

Hereinafter, viewing angle characteristics of the first lens 232 and the second lens 234 will be described with reference to FIGS. 5A and 5B.

FIG. 5A shows an optical profile for a viewing angle of the first lens of the light-emitting display device according to an example embodiment of the present disclosure. FIG. 5B shows an optical profile for a viewing angle of the second lens of the light-emitting display device according to an example embodiment of the present disclosure.

As shown in FIGS. 5A and 5B, the second emission area EA2 provided with the second lens 234 having a half-spherical shape has a narrow viewing angle of less than 30 degrees in up and down directions and left and right directions. Whereas, the first emission area EA1 provided with the first lens 232 having a half-cylindrical shape has a narrow viewing angle of less than 30 degrees in the up and down directions and a wide viewing angle of more than 60 degrees in the left and right directions.

Therefore, when the first emission area EA1 operates, the private viewing mode in the up and down directions and the share viewing mode in the left and right directions can be implemented. Also, when the second emission area EA2 operates, the private viewing mode can be implemented for all four of the up, down, left and right directions.

In the light-emitting display device 100 according to an example embodiment of the present disclosure, a narrow viewing angle in the up and down directions can be achieved by both of the first and second lenses 232 and 234. Also, the share viewing mode and the private viewing mode can be selectively implemented in the left and right directions.

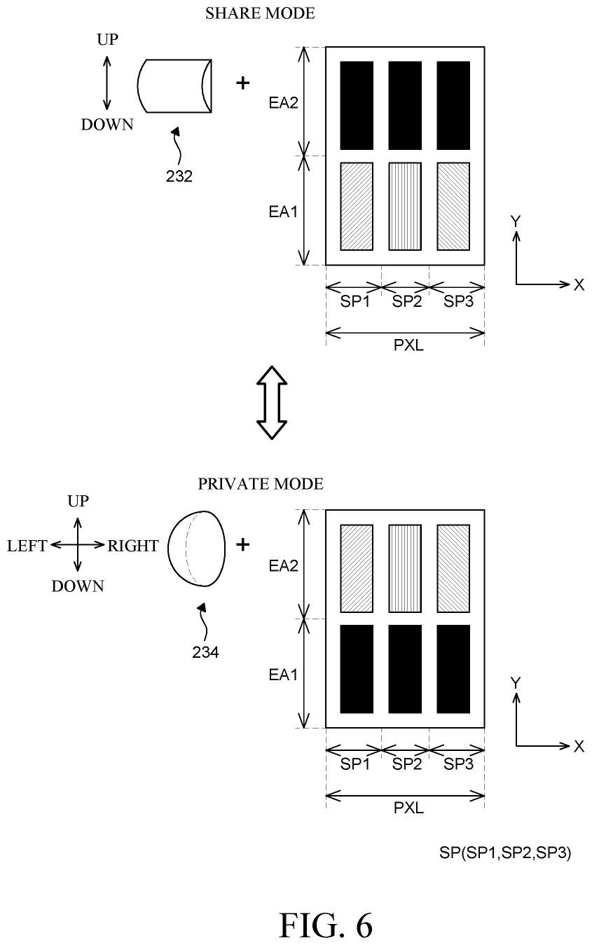

Hereinafter, the share viewing mode and the private viewing mode in the left and right directions will be described with reference to FIG. 6.

FIG. 6 schematically illustrates a share viewing mode operation and a private viewing mode operation of the light-emitting display device according to an example embodiment of the present disclosure.

As shown in FIG. 6, a pixel of the switchable viewing angle light-emitting display device 100 according to an example embodiment of the present disclosure includes the plurality of sub-pixels SP, for example, the first to third sub-pixels SP1, SP2 and SP3. Also, each sub-pixel among the first to third sub-pixels SP1, SP2 and SP3 includes the first emission area EA1 and the second emission area EA2 (e.g., for a total of six light emission areas, but embodiments are not limited thereto).

The first lens 232 having a half-cylindrical shape is provided corresponding to the first emission area EA1, and the second lens 234 having a half-spherical shape is provided corresponding to the second emission area EA2.

In the share viewing mode, the first LED De1 of the first emission area EA1 is turned on and the second LED De2 of the second emission area EA2 is turned off. Also, light emitted from the first LED De1 is limited in viewing angle in the Y-axis direction, e.g., in the up and down directions, by the first lens 232 and output in the X-axis direction, e.g., in the left and right directions, without limitation. For example, a narrow viewing angle is provided along the vertical direction and a wide viewing angle is provided along the horizontal direction.

Meanwhile, in the private viewing mode, the first LED De1 of the first emission area EA1 is turned off and the second LED De2 of the second emission area EA2 is turned on. Also, light emitted from the second LED De2 has a limited viewing angle in all four of the up, down, left and right directions by the second lens 234, and output.

As described above, the light-emitting display device 100 according to an example embodiment of the present disclosure can always have a narrow viewing angle in the up and down directions. If the light-emitting display device 100 according to an example embodiment of the present disclosure having a narrow viewing angle in the up and down directions is applied to a vehicle, it is possible to suppress blocking of the driver's view caused by reflection of an image from a front window of the vehicle.

Also, in the share viewing mode, an image having a wide viewing angle in the left and right directions can be displayed. Further, in the private viewing mode, an image having a narrow viewing angle in the left and right directions can be displayed. In the share viewing mode, both users in a driver seat and a passenger seat can view the same image or watch the same video. In the private viewing mode, one of the users in the driver seat and the passenger seat can view the image or video, while the other users is prevented or limited from viewing the image. Therefore, the share viewing mode and the private viewing mode can be selectively implemented in the left and right directions. Also the private viewing mode can automatically be engaged for any of the active areas according to pre-set conditions, such a light sensor sensing light below a predefined threshold or after a specific time or specific condition (e.g., after 8:00 PM or after sun-set). In this way, the private mode can be automatically engaged by at least one of the active areas in order to facilitate safe driving and prevent the driver from being distracted by bright light or reflections from windows while driving at night or while in a dark tunnel, etc., but embodiments are not limited thereto. Also, the private mode can be automatically engaged for at least one of the active areas when traveling faster than a predefined speed or when predefine conditions are sensed (e.g., the passenger side of the display panel can be switched or transitioned from the share viewing mode to the private viewing mode when the vehicle is traveling faster than 15 mph or when a predetermined number or density of nearby objects is sensed by the vehicle or when traffic congestion is greater than a predefined level, in order to avoid distracting the driver, etc.).

Hereinafter, a configuration and an operation of the plurality of sub-pixels SP will be described in detail.

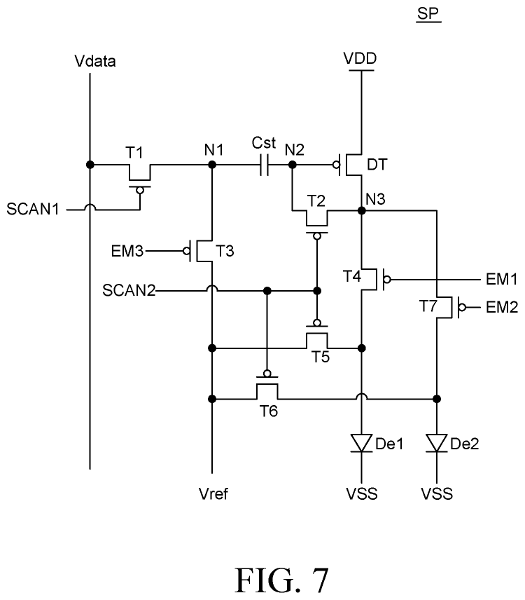

FIG. 7 is a circuit diagram of a sub-pixel of the light-emitting display device according to an example embodiment of the present disclosure.

Referring to FIG. 7, the sub-pixel SP includes a first transistor T1, a second transistor T2, a third transistor T3, a fourth transistor T4, a fifth transistor T5, a sixth transistor T6 and a seventh transistor T7. Also, the sub-pixel SP includes a driving transistor DT, a storage capacitor Cst, the first LED De1 and the second LED De2.

First, switch elements constituting each of the plurality of sub-pixels SP can be implemented with a transistor having an n-type or p-type MOSFET structure. In the following example embodiment, a p-type transistor is illustrated, but the present disclosure is not limited thereto.

Also, the transistor is a three-electrode element including a gate electrode, a source electrode and a drain electrode. The source electrode is an electrode that supplies carriers to the transistor. The carriers start to flow from the source electrode within the transistor. The drain electrode is an electrode from which the carriers in the transistor are discharged to the outside. Also, in a MOSFET, the carriers flow from the source electrode to the drain electrode. In the situation of an n-type MOSFET (NMOS), the carriers are electrons, and, thus, a voltage of the source electrode is lower than a voltage of the drain electrode to enable the electrons to flow from the source electrode to the drain electrode. In the n-type MOSFET, the electrons flow from the source electrode toward the drain electrode, and, thus, a current flows from the drain electrode toward the source electrode. In a p-type MOSFET (PMOS), the carriers are holes, and, thus, a voltage of the source electrode is higher than a voltage of the drain electrode to enable the holes to flow from the source electrode to the drain electrode. In the p-type MOSFET, the holes flow from the source electrode toward the drain electrode, and, thus, a current flows from the source electrode toward the drain electrode. It should be noted that the source electrode and the drain electrode of the MOSFET are not fixed. For example, the source electrode and the drain electrode of the MOSFET can be changed depending on an applied voltage. In the following example embodiment, it should be noted that the present disclosure is not limited by the source electrode and the drain electrode of the transistor.

Referring to FIG. 7, the driving transistor DT controls a driving current applied to a plurality of LEDs (e.g., De1 and De2) depending on a source-gate voltage Vsg. The driving transistor DT includes a source electrode connected to a high-potential driving voltage line supplied with a high-potential driving voltage VDD, a gate electrode connected to a second node N2 and a drain electrode connected to a third node N3.

The first transistor T1 applies the data voltage Vdata from the data line to a first node N1. The first transistor T1 includes a source electrode connected to the data line, a drain electrode connected to the first node N1 and a gate electrode connected to a first scan signal line SL1. The first transistor T1 can transfer the data voltage Vdata from the data line to the first node N1 in response to a first scan signal SCAN1 of a low level which is a turn-on level.

The second transistor T2 diode-connects the gate electrode and the drain electrode of the driving transistor DT. The second transistor T2 includes a drain electrode connected to the second node N2, a source electrode connected to the third node N3 and a gate electrode connected to a second scan signal line SL2. Thus, the second transistor T2 diode-connects the gate electrode and the drain electrode of the driving transistor DT in response to a second scan signal SCAN2 of the low level which is a turn-on level.

The third transistor T3 applies a reference voltage Vref to the first node N1. The third transistor T3 includes a source electrode connected to a reference line that transmits the reference voltage Vref, a drain electrode connected to the first node N1 and a gate electrode connected to a third emission signal line EML3. Therefore, the third transistor T3 can transfer the reference voltage Vref to the first node N1 in response to a third emission signal EM3 of the low level which is a turn-on level.

The fourth transistor T4 forms a current path between the driving transistor DT and the first LED De1 during operation in the share viewing mode. The fourth transistor T4 includes a source electrode connected to the third node N3, a drain electrode connected to the anode electrode of the first LED De1 and a gate electrode connected to a first emission signal line. The fourth transistor T4 forms a current path between the third node N3, which is the source electrode of the fourth transistor T4, and the first LED De1 in response to a first emission signal EM1. Thus, the fourth transistor T4 forms a current path between the driving transistor DT and the first LED De1 in response to the first emission signal EM1 of the low level which is a turn-on level. Therefore, the fourth transistor T4 can also be referred to as a first emission control transistor configured to control emission of the first LED De1.

The fifth transistor T5 applies the reference voltage Vref to the anode electrode of the first LED De1. The fifth transistor T5 includes a source electrode connected to the reference line that transmits the reference voltage Vref, a drain electrode connected to the anode electrode of the first LED De1 and a gate electrode connected to the second scan signal line SL2. Thus, the fifth transistor T5 applies the reference voltage Vref to the anode electrode of the first LED De1 in response to the second scan signal SCAN2 of the low level which is a turn-on level.

The sixth transistor T6 applies the reference voltage Vref to the anode electrode of the second LED De2. The sixth transistor T6 includes a source electrode connected to the reference line that transmits the reference voltage Vref, a drain electrode connected to the anode electrode of the second LED De2 and a gate electrode connected to the second scan signal line SL2. Thus, the sixth transistor T6 applies the reference voltage Vref to the anode electrode of the second LED De2 in response to the second scan signal SCAN2 of the low level which is a turn-on level.

The seventh transistor T7 forms a current path between the driving transistor DT and the second LED De2 during operation in the private viewing mode. The seventh transistor T7 includes a source electrode connected to the third node N3, a drain electrode connected to the anode electrode of the second LED De2 and a gate electrode connected to a second emission signal line EML2. The seventh transistor T7 forms a current path between the third node N3, which is the source electrode of the seventh transistor T7, and the second LED De2 in response to a second emission signal EM2. Thus, the seventh transistor T7 forms a current path between the driving transistor DT and the second LED De2 in response to the second emission signal EM2 of the low level which is a turn-on level. Therefore, the seventh transistor T7 can also be referred to as a second emission control transistor configured to control emission of the second LED De2.

The storage capacitor Cst includes a first electrode connected to the first node N1 and a second electrode connected to the second node N2. Also, one electrode of the storage capacitor Cst is connected to the gate electrode of the driving transistor DT, and the other electrode of the storage capacitor Cst is connected to the first transistor T1. The storage capacitor Cst stores a predetermined voltage to constantly maintain a voltage of the gate electrode of the driving transistor DT while the LED emits light.

The first LED De1 is disposed in the first emission area EA1 and emits light in the share viewing mode. The first lens 232 having a half-cylindrical shape is disposed on the first LED De1, and, thus, the share viewing mode can be implemented. The first LED De1 includes the anode electrode connected to the fourth transistor T4 and the cathode electrode 180 connected to a low-potential driving voltage line applied with a low-potential driving voltage VSS. In the share viewing mode, the first LED De1 is supplied with the driving current of the driving transistor DT through the fourth transistor T4 which is turned on. Thus, during operation in the share viewing mode, the first LED De1 can be supplied with the driving current and can emit light.

The second LED De2 is disposed in the second emission area EA2 and emits light in the private viewing mode. The second lens 234 having a half-spherical shape is disposed on the second LED De2, and, thus, the private viewing mode can be implemented. The second LED De2 includes the anode electrode connected to the seventh transistor T7 and the cathode electrode 180 connected to the low-potential driving voltage line. In the private viewing mode, the second LED De2 is supplied with the driving current of the driving transistor DT through the seventh transistor T7 which is turned on. Thus, during operation in the private viewing mode, the second LED De2 can be supplied with the driving current and can emit light.

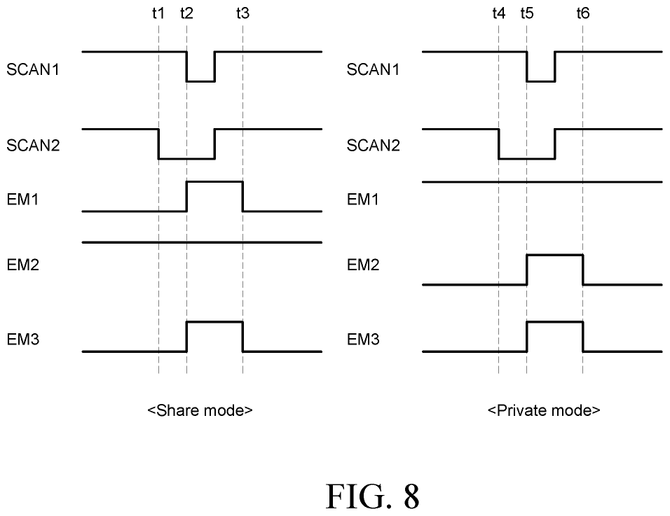

FIG. 8 is a waveform chart showing emission signals and scan signals in each of the share viewing mode and the private viewing mode of the light-emitting display device according to an example embodiment of the present disclosure.

Referring to FIGS. 7 and 8 together, only the first LED De1 may emit light in the share viewing mode, and only the second LED De2 may emit light in the private viewing mode. In the share viewing mode, the second emission signal EM2 for controlling emission of the second LED De2 can be output at a high level, which is a turn-off level, to allow only the first LED De1 to emit light. In the private viewing mode, the first emission signal EM1 for controlling emission of the first LED De1 can be output at the high level, which is a turn-off level, to allow only the second LED De2 to emit light. Also, according to another embodiment, in an increased luminance viewing mode (e.g., a third viewing mode), both of the first LED De1 the second LED De2 may emit light for displaying an image at the same time, in order to provide a higher level of brightness (e.g., which may be helpful on sunny days or when ambient conditions are bright, etc.).

In the share viewing mode, the second scan signal SCAN2 of the low level, the first emission signal EM1 of the low level and the third emission signal EM3 of the low level are output during a time period from a first time point t1 through a second time point t2. The second transistor T2, the fifth transistor T5 and the sixth transistor T6 can be turned on in response to the second scan signal SCAN2 of the low level. Also, the fourth transistor T4 can be turned on in response to the first emission signal EM1 of the low level. Further, the third transistor T3 can be turned on in response to the third emission signal EM3 of the low level.

The first node N1 can be initialized to the reference voltage Vref through the third transistor T3 which is turned on. A voltage of the anode electrode of the first LED De1 can be initialized to the reference voltage Vref through the fifth transistor T5 which is turned on. Also, a voltage of the anode electrode of the second LED De2 can be initialized to the reference voltage Vref through the sixth transistor T6 which is turned on. Further, the driving transistor DT is diode-connected through the second transistor T2 which is turned on, and the gate electrode and the drain electrode of the driving transistor DT are short-circuited. Thus, the driving transistor DT operates like a diode. Furthermore, the reference voltage Vref transferred to the anode electrode of the first LED De1 through the fifth transistor T5 which is turned on is transferred to the third node N3 and the second node N2 through the fourth transistor T4 which is turned on. Thus, the third node N3 and the second node N2 can also be initialized to the reference voltage Vref.

Then, from the second time point t2, the first scan signal SCAN1 of the low level and the second scan signal SCAN2 of the low level can be output, and the first emission signal EM1 can be output at the high level changed from the low level. The first transistor T1 is turned on in response to the first scan signal SCAN1 of the low level at the same time when the third emission signal EM3 of the high level is output and the third transistor T3 is turned off. Thus, the data voltage Vdata can be transferred to the first node N1. Also, the driving transistor DT can be diode-connected through the second transistor T2 which is turned on. Further, a voltage difference between a high-potential power voltage and a threshold voltage can be sampled and supplied to the second node N2.

At a time point between the second time point t2 and a third time point t3, the first scan signal SCAN1 and the second scan signal SCAN2 can be changed to the high level. Also, all the first transistor T1, the second transistor T2, the fifth transistor T5 and the sixth transistor T6 can be turned off. However, even if the first transistor T1 is turned off, the data voltage Vdata input at the second time point t2 can be maintained by the storage capacitor Cst.

Finally, at the third time point t3, the first emission signal EM1 and the third emission signal EM3 of the low level are output, and the second emission signal EM2 of the high level is output. The reference voltage Vref is applied to the first node N1 through the third transistor T3 which is turned on in response to the third emission signal EM3 of the low level. The voltage of the first node N1 can be a voltage difference between the reference voltage Vref and the data voltage Vdata. Such a voltage change can also be applied to the second node N2. A gate-source voltage Vgs of the driving transistor DT can be set to Vdata−Vref+Vth obtained by deducting the reference voltage Vref from the data voltage Vdata and adding threshold voltage Vth to control the driving current.

Then, the driving current can be supplied from the driving transistor DT to the first LED De1 through the fourth transistor T4 which is turned on. Thus, the first LED De1 can emit light. Meanwhile, the second emission signal EM2 is output at the high level, and, thus, the seventh transistor T7 is turned off. Therefore, the driving current from the driving transistor DT may not be transferred to the second LED De2. Accordingly, in the share viewing mode, the driving current is applied only to the first LED De1, and, thus, only the first LED De1 can emit light, while the second LED De2 remains off.

In the private viewing mode, the sub-pixel SP can operate in substantially the same manner as in the share viewing mode, except that the first emission signal EM1 and the second emission signal EM2 are output reversely (e.g., all the wave forms are the same in both modes, except the wave forms for EM1 and EM2 are switched). For instance, in the private viewing mode, the first emission signal EM1 is output at the high level which is a turn-off level, and the second emission signal EM2 can be output at the low level which is a turn-on level from a sixth time point t6 at which the second LED De2 emits light.

Specifically, during a time period from a fourth time point t4 to a fifth time point t5, the first scan signal SCAN1 is output at the high level and the second scan signal SCAN2 is output at the low level. Further, the first emission signal EM1 is output at the high level, and the second emission signal EM2 and the third emission signal EM3 are output at the low level. Thus, the second transistor T2, the fifth transistor T5 and the sixth transistor T6 can be turned on in response to the second scan signal SCAN2. Also, the seventh transistor T7 can be turned on in response to the second emission signal EM2, and the third transistor T3 can be turned on in response to the third emission signal EM3.

The first node N1 can be initialized to the reference voltage Vref through the third transistor T3 which is turned on in response to the third emission signal EM3. Also, the respective anode electrodes of the first LED De1 and the second LED De2 can be initialized to the reference voltage Vref through the fifth transistor T5 and the sixth transistor T6 which are turned on in response to the second scan signal SCAN2. Further, the driving transistor DT is diode-connected through the second transistor T2 which is turned on, and operates like a diode. Finally, the reference voltage Vref transferred to the anode electrode of the second LED De2 through the sixth transistor T6 which is turned on is transferred to the third node N3 and the second node N2 through the seventh transistor T7 which is turned on. Thus, the third node N3 and the second node N2 can also be initialized to the reference voltage Vref.

Then, from the fifth time point t5, the first scan signal SCAN1 of the low level and the second scan signal SCAN2 of the low level can be output, and the second emission signal EM2 and the third emission signal EM3 can be output at the high level changed from the low level. When the third emission signal EM3 of the high level is output, the third transistor T3 can be turned off. Also, the first transistor T1 can be turned on in response to the first scan signal SCAN1 of the low level. Thus, the data voltage Vdata can be transferred to the first node N1. Also, the driving transistor DT can be diode-connected through the second transistor T2 which is turned on. Further, a voltage difference between the high-potential power voltage and the threshold voltage can be sampled and supplied to the second node N2.

Finally, at the sixth time point t6, the second emission signal EM2 and the third emission signal EM3 of the low level are output and the first emission signal EM1 of the high level is output. The reference voltage Vref is applied to the first node N1 through the third transistor T3 which is turned on in response to the third emission signal EM3 of the low level. The voltage of the first node N1 can be a voltage difference between the reference voltage Vref and the data voltage Vdata. Such a voltage change can also be applied to the second node N2. The gate-source voltage Vgs of the driving transistor DT can be set to Vdata−Vref+Vth obtained by deducting the reference voltage Vref from the data voltage Vdata and adding threshold voltage Vth to control the driving current.

Then, the driving current can be supplied from the driving transistor DT to the second LED De2 through the seventh transistor T7 which is turned on. Thus, the second LED De2 can emit light. Meanwhile, the first emission signal EM1 is output at the high level, and, thus, the fourth transistor T4 is turned off. Therefore, the driving current from the driving transistor DT may not be transferred to the first LED De1 and the first LED De1 remains off while the second LED De2 emits light. Accordingly, in the private viewing mode, the driving current is applied only to the second LED De2, and, thus, only the second LED De2 can emit light while the first LED De1 remains off.

Hereinafter, operations of the first active area AA1 and the second active area AA2 will be described with reference to FIGS. 9 and 10.

FIG. 9 is a schematic enlarged plan view of the display panel of the light-emitting display device according to an example embodiment of the present disclosure. FIG. 10 is a schematic enlarged plan view of the display panel operating in the share viewing mode and the private viewing mode. For the convenience of description, FIGS. 9 and 10 enlarge and illustrate only a part of the display panel PN.

Referring to FIG. 9, the gate driver GD is disposed on a part of the non-active area NA, e.g., the bezel area BA, in the display panel PN. The gate driver GD includes a plurality of scan signal generators GDS and a plurality of emission signal generators GDE disposed in the bezel area BA under the first active area AA1 and the second active area AA2. Further, the plurality of scan signal generators GDS include a plurality of first scan signal generators GDS1 and a plurality of second scan signal generators GDS2. Furthermore, the plurality of emission signal generators GDE include a plurality of first emission signal generators GDE1, a plurality of second emission signal generators GDE2 and a plurality of third emission signal generators GDE3.

The plurality of first scan signal generators GDS1 can output the first scan signal SCAN1 to the first scan signal line SL1 in the first active area AA1 (e.g., the left side of the display device, which can correspond to the driver's side) and the second active area AA2 (e.g., the right side of the display device, which can correspond to the passenger's side). The plurality of first scan signal generators GDS1 can be connected to the first scan signal line SL1, and the first scan signal SCAN1 can be multi-output to the first scan signal line SL1. In this situation, the first scan signal SCAN1 is simultaneously input to the first scan signal line SL1 through many points in the first scan signal line SL1. Therefore, it is possible to suppress a delay of the first scan signal SCAN1 transferred through the first scan signal line SL1 and reduce or prevent a voltage drop. Also, it is possible to reduce a deviation of the first scan signal SCAN1 transferred to the plurality of sub-pixels SP connected to the first scan signal line SL1 and noise can be prevented or eliminated.

The plurality of second scan signal generators GDS2 can output the second scan signal SCAN2 to the second scan signal line SL2 in the first active area AA1 and the second active area AA2. The plurality of second scan signal generators GDS2 can be connected to the second scan signal line SL2, and the second scan signal SCAN2 can be multi-output to the second scan signal line SL2. The second scan signal SCAN2 is simultaneously input to the second scan signal line SL2 through many points in the second scan signal line SL2. Therefore, is possible to suppress a delay of the second scan signal SCAN2 transferred through the second scan signal line SL2 and reduce or prevent a voltage drop. Also, it is possible to reduce a deviation of the second scan signal SCAN2 transferred to the plurality of sub-pixels SP connected to the second scan signal line SL2 and noise can be prevented or eliminated.

If a scan signal is applied to only one point of the scan signal line SL, a delay can occur while the scan signal is transferred to the other end of the scan signal line (e.g., especially for a large display device). Thus, a delay deviation of the scan signals can occur in the plurality of scan signal lines SL, which can impair image quality.

Meanwhile, as in the light-emitting display device 100 according to an example embodiment of the present disclosure, the plurality of scan signal generators GDS are formed and scan signals are applied from many points to a scan signal line SL. Thus, it is possible to minimize a delay of the scan signal.

Then, the plurality of first emission signal generators GDE1 can output the first emission signal EM1 to the plurality of first emission signal lines EML1, respectively. For example, the plurality of first emission signal lines EML1 disposed in the first active area AA1 can be connected to the plurality of first emission signal generators GDE1 disposed in the bezel area BA under the first active area AA1. Thus, the plurality of first emission signal lines EML1 can be applied with the first emission signal EM1.

The plurality of second emission signal generators GDE2 can output the second emission signal EM2 to the second emission signal line EML2, respectively. For example, the plurality of second emission signal lines EML2 disposed in the first active area AA1 can be connected to the plurality of second emission signal generators GDE2 disposed in the bezel area BA under the first active area AA1. Thus, the plurality of second emission signal lines EML2 can be applied with the second emission signal EM2.

Also, the plurality of third emission signal generators GDE3 can output the third emission signal EM3 to the plurality of third emission signal lines EML3. In this situation, the third emission signal EM3 can be multi-output from the plurality of third emission signal generators GDE3 to each of the plurality of third emission signal lines EML3. For example, the third emission signal line EML3 can be simultaneously applied with the third emission signal EM3 from the third emission signal generator GDE3 disposed in the bezel area BA under the first active area AA1 and the third emission signal generator GDE3 disposed in the bezel area BA under the second active area AA2. Therefore, the third emission signal EM3 is simultaneously input to the third emission signal line EML3 through many points in the third emission signal line EML3. Accordingly, it is possible to suppress a delay of the third emission signal EM3 transferred through the third emission signal line EML3.

Meanwhile, the plurality of scan signal lines SL and the plurality of third emission signal lines EML3 continuously extend throughout the first active area AA1 and the second active area AA2. However, the plurality of first emission signal lines EML1 and the plurality of second emission signal line EML2 are separated at the boundary between the first active area AA1 and the second active area AA2 (e.g., this separate can correspond to the driver's side of the display on one half and the passenger's side of the display on the other half, but is not limited thereto). Thus, a first emission signal line EML1 disposed in the first active area AA1 can be separated and spaced apart from a first emission signal line EML1 disposed in the second active area AA2. Also, a second emission signal line EML2 disposed in the first active area AA1 can be separated and spaced apart from a second emission signal line EML2 disposed in the second active area AA2. In addition, according to another embodiment, the display device can be divided into more than just two different active areas. For example, the display device can include three or more active areas and the display device can be applied to many different situations and settings. For example, a large display device can be used by a group of individuals in a video gaming setting or a lecture/test taking setting, in which each active area of the screen can correspond to a different user, and the active areas can be individually controlled to implement the public viewing mode or the private viewing mode (e.g., the active areas can be set to the public viewing mode during a lecture, and then switched to the private viewing mode during an exam or for individual note taking, or selectively switching during different parts of a video game tournament session, etc.). Also, the display device can be shared by a group of airline passengers seated within a same row during a flight, and the active areas can all be set to the public viewing mode to display a same video, such as an in-flight safety video, and then the different areas can be set to the private viewing mode later so each passenger can watch a different movie or program.

For example, the plurality of first emission signal lines EML1 includes a plurality of first-first emission signal lines EML1-1 disposed in the first active area AA1 and configured to transfer the first emission signal EM1 to sub-pixels SP in the first active area AA1. Also, the plurality of first emission signal lines EML1 include a plurality of first-second emission signal lines EML1-2 disposed in the second active area AA2 and configured to transfer the first emission signal EM1 to sub-pixels SP in the second active area AA2. The plurality of second emission signal lines EML2 include a plurality of second-first emission signal lines EML2-1 disposed in the first active area AA1 and configured to transfer the second emission signal EM2 to sub-pixels SP in the first active area AA1. Also, the plurality of second emission signal lines EML2 include a plurality of second-second emission signal lines EML2-2 disposed in the second active area AA2 and configured to transfer the second emission signal EM2 to sub-pixels SP in the second active area AA2.

In this situation, the first emission signal EM1 can be transmitted to the plurality of first-first emission signal lines EML1-1 from the plurality of first emission signal generators GDE1 disposed in the bezel area BA under the first active area AA1. Also, the first emission signal EM1 can be transmitted to the plurality of first-second emission signal lines EML1-2 from the plurality of first emission signal generators GDE1 disposed in the bezel area BA under the second active area AA2. Further, the second emission signal EM2 can be transmitted to the plurality of second-first emission signal lines EML2-1 from the plurality of second emission signal generators GDE2 disposed in the bezel area BA under the first active area AA1. Furthermore, the second emission signal EM2 can be transmitted to the plurality of second-second emission signal lines EML2-2 from the plurality of second emission signal generators GDE2 disposed in the bezel area BA under the second active area AA2.

Meanwhile, the gate driver GD is disposed in the bezel area BA under the active area AA or on a rear side of the display device. Also, the plurality of scan signal lines SL and the plurality of emission signal lines EML supplied with a scan signal and an emission signal from the gate driver GD can extend in a row direction. Thus, a plurality of auxiliary lines CL are disposed to connect the plurality of scan signal lines SL and the plurality of emission signal lines EML extending in the row direction, to the gate driver GD disposed under the active area AA or on a rear side of the display device. The plurality of auxiliary lines CL extend in a column direction from the bezel area BA toward the active area AA. Also, the plurality of auxiliary lines CL can electrically connect the plurality of scan signal lines SL and the plurality of emission signal lines EML to the gate driver GD. The plurality of auxiliary lines CL can be disposed between the plurality of sub-pixels SP in the active area AA and can be connected to the plurality of scan signal lines SL and the plurality of emission signal lines EML.

The plurality of auxiliary lines CL include a first scan signal auxiliary line CLS1 connecting the first scan signal generator GDS1 to the first scan signal line SL1. Also, the plurality of auxiliary lines CL include a second scan signal auxiliary line CLS2 connecting the second scan signal generator GDS2 to the second scan signal line SL2. Further, the plurality of auxiliary lines CL include a first emission signal auxiliary line CLE1 connecting the first emission signal line EML1 to the first emission signal generator GDE1. Furthermore, the plurality of auxiliary lines CL include a second emission signal auxiliary line CLE2 connecting the second emission signal line EML2 to the second emission signal generator GDE2. Also, the plurality of auxiliary lines CL include a third emission signal auxiliary line CLE3 connecting the third emission signal line EML3 to the third emission signal generator GDE3.

Herein, the plurality of sub-pixels SP are disposed in a plurality of rows and a plurality of columns. The plurality of sub-pixels SP can be composed of sub-pixel groups PU disposed in each of the plurality of respective rows. Also, the plurality of scan signal lines SL and the plurality of emission signal lines EML can be disposed in each of the plurality of rows, and can be connected to a sub-pixel group PU disposed in each of the plurality of rows. Thus, the plurality of auxiliary lines CL can connect the plurality of scan signal lines SL and the plurality of emission signal lines EML disposed in each of the plurality of rows to the gate driver GD. For example, the plurality of scan signal lines SL and the plurality of emission signal lines EML connected to the sub-pixel group PU1 in a first row can be connected to at least one scan signal generator GDS and at least one emission signal generator GDE through the plurality of auxiliary lines CL. The plurality of scan signal lines SL and the plurality of emission signal lines EML connected to the sub-pixel group PU(N) in the last Nth row can also be connected to at least one scan signal generator GDS and at least one emission signal generator GDE through the plurality of auxiliary lines CL.

Meanwhile, in the light-emitting display device 100 according to an example embodiment of the present disclosure, the first emission signal lines EML1 and the second emission signal lines EML2 disposed in each of the first active area AA1 and the second active area AA2 are separated (e.g., first emission signal lines EML1 on the left half of the screen, while the second emission signal lines EML2 are on the right half of the screen, but embodiments are not limited thereto). Thus, the first active area AA1 and the second active area AA2 can operate independently in the share viewing mode or the private viewing mode. For example, while the first active area AA1 operates in the share viewing mode, the second active area AA2 can operate in the private viewing mode or the share viewing mode. Also, while the second active area AA2 operates in the private viewing mode, the second active area AA2 can operate in the private viewing mode or the share viewing mode.

For example, as shown in FIG. 10, when the first active area AA1 operates in the share viewing mode and the second active area AA2 operates in the private viewing mode, only the first emission signal generator GDE1 among the first emission signal generator GDE1 and the second emission signal generator GDE2 in the first active area AA1 output the first emission signal EM1 of the low level which is a turn-on level. In this situation, the fourth transistor T4 configured to form a current path between the first LED De1 and the driving transistor DT can be turned on and can transfer a driving current. Also, the seventh transistor T7 configured to form a current path between the second LED De2 and the driving transistor DT can maintain a turn-off state. Also, the plurality of sub-pixels SP disposed in the first active area AA1 can emit light by means of the first emission area EA1 on the first LED De1, and, thus, the first active area AA1 can operate in the share viewing mode.

If the second active area AA2 operates in the private viewing mode while the first active area AA1 operates in the share viewing mode, only the second emission signal generator GDE2 among the first emission signal generator GDE1 and the second emission signal generator GDE2 in the second active area AA2 may output the second emission signal EM2 of the low level which is a turn-on level. In this situation, the seventh transistor T7 configured to form a current path between the second LED De2 and the driving transistor DT can be turned on and can transfer a driving current to the first LED De1. Also, the fourth transistor T4 configured to form a current path between the first LED De1 and the driving transistor DT can maintain a turn-off state. Also, the plurality of sub-pixels SP disposed in the second active area AA2 can emit light by means of the second emission area EA2 on the second LED De2, and, thus, the second active area AA2 can operate in the private viewing mode.

In this situation, even when the first emission signal generator GDE1 in the first active area AA1 outputs the first emission signal EM1 of the low level, the first emission signal EM1 of the low level is not transferred to the second active area AA2. This is because the first-first emission signal line EML1-1 in the first active area AA1 is separated from the first-second emission signal line EML1-2 in the second active area AA2. Also, when the second emission signal generator GDE2 in the second active area AA2 outputs the second emission signal EM2 of the low level, the second emission signal EM2 of the low level is not transferred to the first active area AA1. This is because the second-first emission signal line EML2-1 in the first active area AA1 is separated from the second-second emission signal line EML2-2 in the second active area AA2. Therefore, the plurality of first emission signal generators GDE1 and the plurality of second emission signal generators GDE2 are disposed in the bezel area BA to correspond to the first active area AA1 and the second active area AA2, respectively. Also, the plurality of first emission signal lines EML1 and the plurality of second emission signal lines EML2 disposed in the first active area AA1 and the second active area AA2 are separated from each other. Thus, it is possible to independently operate the first active area AA1 and the second active area AA2 in the share viewing mode and the private viewing mode.

For another example, if the first active area AA1 operates in the private viewing mode and the second active area AA2 operates in the share viewing mode, the gate driver GD can output an emission signal of the low level which is a turn-on level only to the second-first emission signal line EML2-1 in the first active area AA1 and the first-second emission signal line EML1-2 in the second active area AA2.

For yet another example, if both the first active area AA1 and the second active area AA2 operate in the share viewing mode, the gate driver GD can output an emission signal of the low level which is a turn-on level only to the first-first emission signal line EML1-1 in the first active area AA1 and the first-second emission signal line EML1-2 in the second active area AA2.

For still another example, if both the first active area AA1 and the second active area AA2 operate in the private viewing mode, the gate driver GD can output an emission signal of the low level which is a turn-on level only to the second-first emission signal line EML2-1 in the first active area AA1 and the second-second emission signal line EML2-2 in the second active area AA2.

Therefore, in the light-emitting display device 100 according to an example embodiment of the present disclosure, the first emission signal line EML1 and the second emission signal line EML2 disposed in the first active area AA1 and the second active area AA2 are separated from each other. Also, the first emission signal generator GDE1 and the second emission signal generator GDE2 are connected to the divided first and second emission signal lines EML1 and EML2, respectively. Thus, it is possible to independently control the share viewing mode and the private viewing mode of the first active area AA1 and the second active area AA2. The first emission signal line EML1 is divided into the first-first emission signal line EML1-1 in the first active area AA1 and the first-second emission signal line EML1-2 in the second active area AA2. Thus, the second active area AA2 can operate in the share viewing mode regardless of a mode of the first active area AA1. Also, the first active area AA1 can operate in the share viewing mode regardless of a mode of the second active area AA2. Further, the second emission signal line EML2 is divided into the second-first emission signal line EML2-1 in the first active area AA1 and the second-second emission signal line EML2-2 in the second active area AA2. Thus, the second active area AA2 can operate in the private viewing mode regardless of a mode of the first active area AA1. Also, the first active area AA1 can operate in the private viewing mode regardless of a mode of the second active area AA2. Therefore, in the light-emitting display device 100 according to an example embodiment of the present disclosure, a specific area of the screen can be selectively and freely switched to any one of the share viewing mode and the private viewing mode.

In the light-emitting display device 100 according to an example embodiment of the present disclosure, the plurality of scan signal generators GDS and the plurality of emission signal generators GDE are partially disposed only in the non-active area NA on one side of the active area AA. Thus, the size of the remaining non-active area NA can be minimized. For example, the gate driver GD can be disposed in the non-active area NA adjacent to one of the four sides of the active area AA, e.g., only in the bezel area BA. Thus, the size of the non-active area NA adjacent to the other three sides of the active area AA can be minimized. Particularly, the size of the non-active area NA on both sides of the active area AA can be reduced. Thus, the light-emitting display device 100 can be implemented in various designs. Since the gate driver GD is disposed on one side of the active area AA, the plurality of auxiliary lines CL connecting the gate driver GD to the plurality of scan signal lines SL and the plurality of emission signal lines EML can be formed. Thus, a signal from the gate driver GD can be easily transferred to the plurality of sub-pixels SP.

In the light-emitting display device 100 according to an example embodiment of the present disclosure, it is possible to suppress a delay of a signal transferred to each of the plurality of scan signal lines SL and the plurality of emission signal lines EML. For example, the plurality of scan signal generators GDS can simultaneously apply a scan signal to each scan signal line SL. Also, a scan signal can be multi-output to each scan signal line SL. Since the scan signal is applied to a scan signal line SL from many different points, a delay of the scan signal transferred to the entire scan signal line SL can be suppressed. Further, at least one emission signal generator GDE can be connected to each of the plurality of emission signal lines EML and can multi-output an emission signal. Therefore, in the light-emitting display device 100 according to an example embodiment of the present disclosure, at least one scan signal generator GDS is connected to each of the plurality of scan signal lines SL, and at least one emission signal generator GDE is connected to each of the plurality of emission signal lines EML. Thus, it is possible to suppress a delay of a scan signal and an emission signal transferred to the plurality of sub-pixels SP, and reduce a consequent deviation. Further, a signal output from the gate driver GD is transferred to the plurality of scan signal lines SL and the plurality of emission signal lines EML extending in the row direction through the auxiliary lines CL extending in the column direction. Thus, a signal delay in the row direction can be suppressed. Therefore, the resolution along the row direction can be increased and higher resolution and improved image quality can be provided.

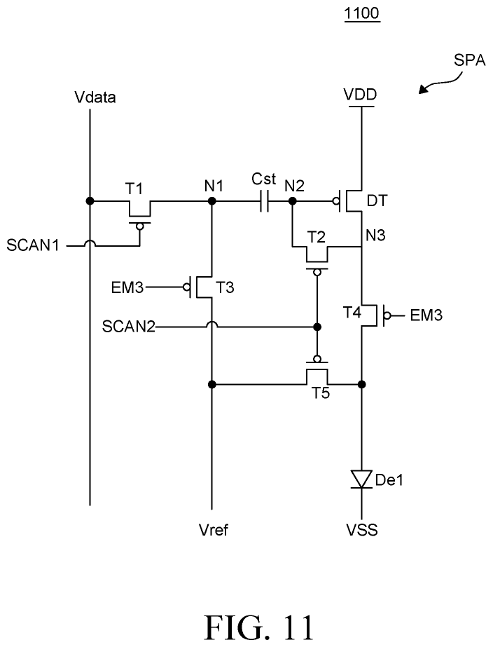

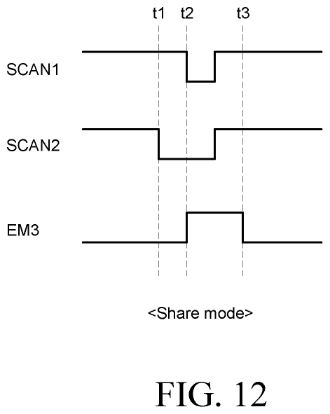

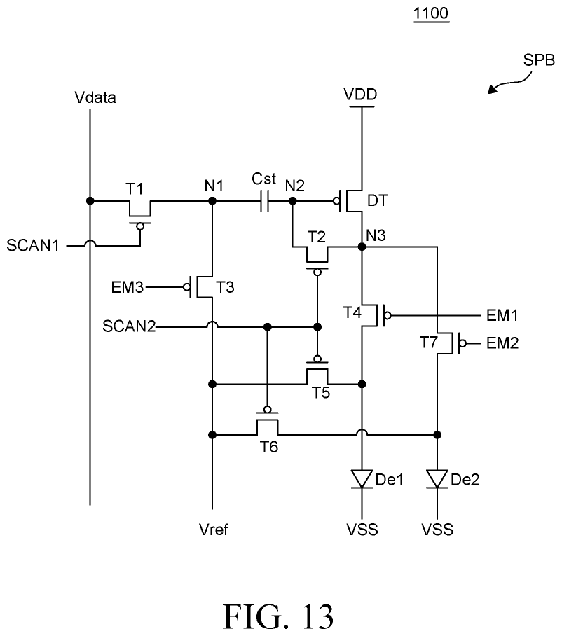

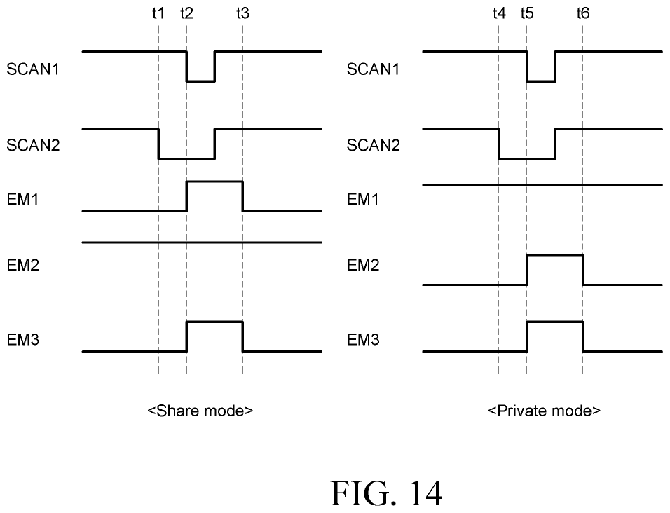

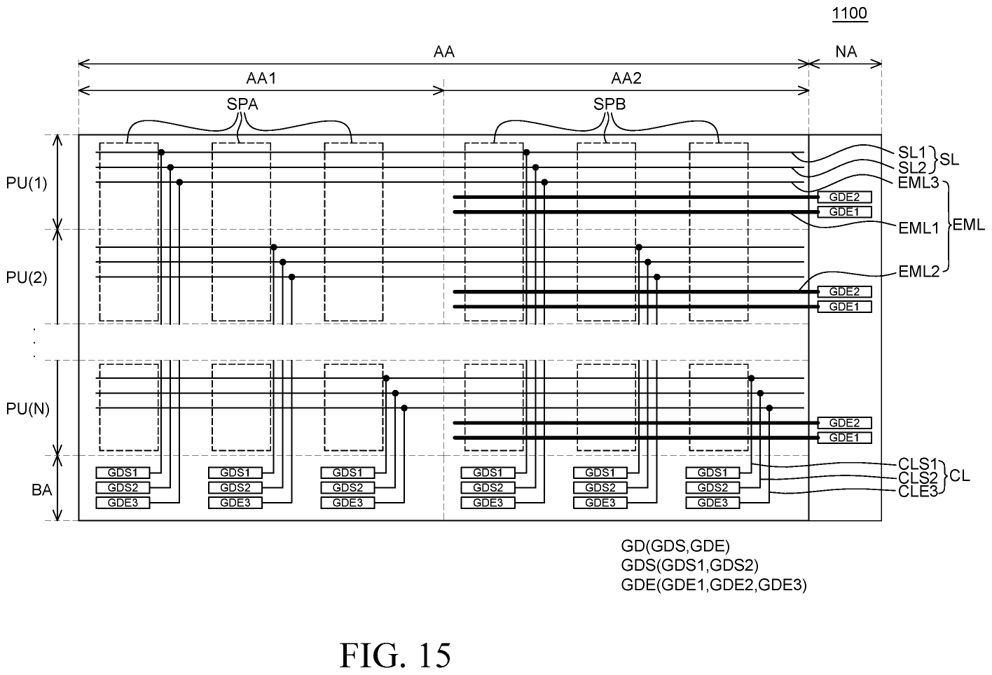

FIG. 11 is a circuit diagram of a first sub-pixel of a light-emitting display device according to another example embodiment of the present disclosure. FIG. 12 is a waveform chart showing emission signals and scan signals of the light-emitting display device according to another example embodiment of the present disclosure. FIG. 13 is a circuit diagram of a second sub-pixel of the light-emitting display device according to another example embodiment of the present disclosure. FIG. 14 is a waveform chart showing emission signals and scan signals in each of the share viewing mode and the private viewing mode of the light-emitting display device according to another example embodiment of the present disclosure. FIG. 15 is a schematic enlarged plan view of a display panel of the light-emitting display device according to another example embodiment of the present disclosure. A light-emitting display device 1100 shown in FIGS. 11 to 15 is substantially the same as the light-emitting display device 100 shown in FIGS. 1 to 10 except for configurations of the sub-pixel SP, the plurality of emission signal lines EML and the gate driver GD. Therefore, a redundant description will be omitted.

Referring to FIG. 15, the first active area AA1 can operate only in the share viewing mode, and the second active area AA2 can operate in the share viewing mode and the private viewing mode. Thus, in the plurality of sub-pixels SP of the first active area AA1, only the first lens 232 and the first LED De1 may be disposed. However, in the plurality of sub-pixels SP of the second active area AA2, all of the first lens 232, the first LED De1, the second lens 234 and the second LED De2 can be disposed.

The plurality of sub-pixels SP include a plurality of first sub-pixels SPA disposed in the first active area AA1 and a plurality of second sub-pixels SPB disposed in the second active area AA2. The plurality of first sub-pixels SPA operate only in the share viewing mode and thus each of the first sub-pixels SPA includes only one first LED De1 (e.g., the second LED De2 is not provided). However, the plurality of second sub-pixels SPB can include both of the first LED De1 configure to operate in the share viewing mode and the second LED De2 configured to operate in the private viewing mode.

Specifically, referring to FIG. 11, each of the plurality of first sub-pixels SPA includes the first transistor T1, the second transistor T2, the third transistor T3 and the fourth transistor T4. Also, each of the plurality of first sub-pixels SPA includes the fifth transistor T5, the driving transistor DT, the storage capacitor Cst and the first LED De1.

The driving transistor DT controls a driving current applied to a plurality of LEDs depending on the source-gate voltage Vsg. The driving transistor DT includes a source electrode connected to the high-potential driving voltage line, a gate electrode connected to the second node N2 and a drain electrode connected to the third node N3.

The first transistor T1 applies the data voltage Vdata from the data line to the first node N1. The first transistor T1 includes a source electrode connected to the data line, a drain electrode connected to the first node N1 and a gate electrode connected to the first scan signal line SL1. The first transistor T1 can transfer the data voltage Vdata from the data line to the first node N1 in response to the first scan signal SCAN1 of the low level which is a turn-on level.

The second transistor T2 diode-connects the gate electrode and the drain electrode of the driving transistor DT. The second transistor T2 includes a drain electrode connected to the second node N2, a source electrode connected to the third node N3 and a gate electrode connected to the second scan signal line SL2. Thus, the second transistor T2 diode-connects the gate electrode and the drain electrode of the driving transistor DT in response to the second scan signal SCAN2 of the low level which is a turn-on level.

The third transistor T3 applies the reference voltage Vref to the first node N1. The third transistor T3 includes a source electrode connected to the reference line that transmits the reference voltage Vref, a drain electrode connected to the first node N1 and a gate electrode connected to the third emission signal line EML3. Therefore, the third transistor T3 can transfer the reference voltage Vref to the first node N1 in response to the third emission signal EM3 of the low level which is a turn-on level.

The fourth transistor T4 forms a current path between the driving transistor DT and the first LED De1. The fourth transistor T4 includes a source electrode connected to the third node N3, a drain electrode connected to the anode electrode of the first LED De1 and a gate electrode connected to the first emission signal line. The fourth transistor T4 forms a current path between the third node N3, which is the source electrode of the fourth transistor T4, and the first LED De1 in response to the third emission signal line EML3. Thus, the fourth transistor T4 forms a current path between the driving transistor DT and the first LED De1 in response to the third emission signal line EML3 of the low level which is a turn-on level.

The fifth transistor T5 applies the reference voltage Vref to the anode electrode of the first LED De1. The fifth transistor T5 includes a source electrode connected to the reference line that transmits the reference voltage Vref, a drain electrode connected to the anode electrode of the first LED De1 and a gate electrode connected to the second scan signal line SL2. Thus, the fifth transistor T5 applies the reference voltage Vref to the anode electrode of the first LED De1 in response to the second scan signal SCAN2 of the low level which is a turn-on level.

The storage capacitor Cst includes a first electrode connected to the first node N1 and a second electrode connected to the second node N2. Configured to be, one electrode of the storage capacitor Cst is connected to the gate electrode of the driving transistor DT, and the other electrode of the storage capacitor Cst is connected to the first transistor T1. The storage capacitor Cst stores a predetermined voltage to constantly maintain a voltage of the gate electrode of the driving transistor DT while the LED emits light.

The first LED De1 is a self-emitting element that emits light in response to the driving current. Light emitted from the first LED De1 can be transferred to the first lens 232. The first lens 232 having a half-cylindrical shape is disposed on the first LED De1, and, thus, the share viewing mode can be implemented. The first LED De1 includes the anode electrode connected to the fourth transistor T4 and the cathode electrode 180 connected to the low-potential driving voltage line. The first LED De1 can be supplied with the driving current of the driving transistor DT through the fourth transistor T4 and can emit light.

Referring to FIG. 12, the first sub-pixel SPA includes only the first LED De1, and only the first lens 232 is disposed on the first sub-pixel SPA. Thus, the first active area AA1 in which the plurality of first sub-pixels SPA are disposed can operate only in the share viewing mode.

First, during a time period from the time point t1 through the second time point t2, the second scan signal SCAN2 of the low level, and the third emission signal EM3 of the low level are output. The second transistor T2, the fifth transistor T5 and the sixth transistor T6 can be turned on in response to the second scan signal SCAN2 of the low level. Also, the fourth transistor T4 can be turned on in response to the third emission signal EM3 of the low level. Further, the third transistor T3 can be turned on in response to the third emission signal EM3 of the low level.

A voltage of the first node N1 and a voltage of the anode electrode of the first LED De1 can be initialized to the reference voltage Vref through the third transistor T3 and the fifth transistor T5 which are turned on. Also, the driving transistor DT can be diode-connected through the second transistor T2 which is turned on. Further, the reference voltage Vref transferred to the anode electrode of the first LED De1 through the fifth transistor T5 which is turned on is transferred to the third node N3 and the second node N2 through the fourth transistor T4 which is turned on. Thus, the third node N3 and the second node N2 can also be initialized to the reference voltage Vref.

Then, from the second time point t2, the first scan signal SCAN1 of the low level and the second scan signal SCAN2 of the low level can be output, and the third emission signal EM3 can be output at the high level from the low level. The first transistor T1 is turned on in response to the first scan signal SCAN1 of the low level at the same time when the third emission signal EM3 of the high level is output and the third transistor T3 is turned off. Thus, the data voltage Vdata can be transferred to the first node N1. Also, the driving transistor DT can be diode-connected through the second transistor T2 which is turned on. Further, a voltage difference between a high-potential power voltage and a threshold voltage can be sampled and supplied to the second node N2.

At a time point between the second time point t2 and a third time point t3, the first scan signal SCAN1 and the second scan signal SCAN2 can be changed to the high level. Also, all the first transistor T1, the second transistor T2 and the fifth transistor T5 can be turned off. However, even if the first transistor T1 is turned off, the data voltage Vdata input at the second time point t2 can be maintained by the storage capacitor Cst.

Finally, at the third time point t3, the third emission signal EM3 of the low level is output. The reference voltage Vref is applied to the first node N1 through the third transistor T3 which is turned on in response to the third emission signal EM3 of the low level. The voltage of the first node N1 can be a voltage difference between the reference voltage Vref and the data voltage Vdata. Such a voltage change can also be applied to the second node N2. The gate-source voltage Vgs of the driving transistor DT can be set to Vdata−Vref+Vth obtained by deducting the reference voltage Vref from the data voltage Vdata and adding the threshold voltage Vth to control the driving current. Therefore, the first LED De1 can emit light by supplying the driving current from the driving transistor DT to the first LED De1 through the fourth transistor T4 which is turned on.

Referring to FIG. 13, each of the plurality of second sub-pixels SPB in the second active area AA2 includes the first transistor T1, the second transistor T2, the third transistor T3, the fourth transistor T4 and the fifth transistor T5. Also, each of the plurality of second sub-pixels SPB includes the sixth transistor T6, the seventh transistor T7, the driving transistor DT, the storage capacitor Cst, the first LED De1 and the second LED De2. The plurality of second sub-pixels SPB can further include the sixth transistor T6 and the seventh transistor T7 as compared to the plurality of first sub-pixels SPA. Further, the plurality of second sub-pixels SPB can be further connected to the first emission signal line EML1 and the second emission signal line EML2 as compared to the plurality of first sub-pixels SPA (e.g., which use the third emission line EML3).

The plurality of second sub-pixels SPB have substantially the same circuit configuration as the sub-pixel SP of the light-emitting display device 100 according to an example embodiment of the present disclosure shown in FIGS. 7 and 8. Thus, the plurality of second sub-pixels SPB can operate in the same manner as the sub-pixel SP of the light-emitting display device 100.

For example, during operation in the share viewing mode, the first emission signal EM1 and the third emission signal EM3 of the low level can be applied to the second sub-pixel SPB, and only the first LED De1 can emit light. However, during operation in the private viewing mode, the second emission signal EM2 and the third emission signal EM3 of the low level can be applied to the second sub-pixel SPB, and only the second LED De2 can emit light. Therefore, in the plurality of second sub-pixels SPB, only one of the first LED De1 and the second LED De2 is selected and emits light. Thus, any one of the share viewing mode and the private viewing mode can be operated.

The plurality of emission signal lines EML are connected to the first sub-pixel SPA and the second sub-pixel SPB in different configurations. Thus, the plurality of emission signal lines EML disposed in the first active area AA1 and the second active area AA2 can be modified in arrangement. Accordingly, the gate driver GD can be modified in arrangement. Also, in this way, resources can be conserved and manufacturing costs can be reduced, especially for display devices that include an area of the screen that does not require the private viewing mode, e.g., such as an area of the screen that should always provide the share viewing mode and have a wide viewing angle, such as being providing public information or information that should be seen by multiple users at the same time (e.g., a top area of the screen or a both area of the screen can be designated as only for providing the share viewing mode, but embodiments are not limited thereto). According to another embodiment, a certain area of the screen can be designated to only provide the private viewing mode and have sub-pixels that only include the second lens 234 having a half-spherical shape.

Referring to FIG. 15, only the third emission signal line EML3 among the plurality of emission signal lines EML can be disposed in the first active area AA1. Thus, in the bezel area BA under the first active area AA1, the plurality of scan signal generators GDS and only the plurality of third emission signal generators GDE3 among the plurality of emission signal generators GDE can be disposed. Also, the third emission signal line EML3 can extend all the way across both of the first active area AA1 and the second active area AA2 without being separated.

In the second active area AA2, all the plurality of emission signal lines EML can be disposed. For example, the first emission signal line EML1, the second emission signal line EML2 and the third emission signal line EML3 can be disposed in each of a plurality of rows. Further, in the bezel area BA under the second active area AA2, the plurality of scan signal generators GDS and the plurality of third emission signal generators GDE3 is disposed to output signals to the plurality of scan signal lines SL and the third emission signal line EML3.

In the second active area AA2, the first emission signal line EML1 and the second emission signal line EML2 are further disposed. Therefore, the first emission signal generator GDE1 and the second emission signal generator GDE2 can be further needed. However, if the first emission signal generator GDE1 and the second emission signal generator GDE2 are to be disposed in the bezel area BA under the second active area AA2, the overall size of the bezel area BA may increase. Thus, the size of the bezel area BA under the first active area AA1 where the first emission signal generator GDE1 and the second emission signal generator GDE2 are not disposed in order to save space and reduce manufacturing costs.

Thus, in the light-emitting display device 1100 according to another example embodiment of the present disclosure, the first emission signal generator GDE1 and the second emission signal generator GDE2 are disposed in the lateral non-active area NA adjacent to ends of the first emission signal line EML1 and the second emission signal line EML2 (e.g., only on the right side or only on the passenger side). Therefore, the size of the bezel area BA can be reduced since the first emission signal generator GDE1 and the second emission signal generator GDE2 are not provided on the left side of the first active area AA1 (e.g., the driver's side). Further, the first emission signal generator GDE1 and the second emission signal generator GDE2 can be directly connected to the ends of the first emission signal line EML1 and the second emission signal line EML2, respectively. Thus, the first emission signal generator GDE1 and the second emission signal generator GDE2 can output emission signals. Therefore, the first emission signal auxiliary line CLE1 and the second emission signal auxiliary line CLE2 extending in the column direction can be removed. Accordingly, the size of a contact area between the plurality of auxiliary lines CL and the plurality of emission signal lines EML, e.g., an area between the plurality of second sub-pixels SPB can be reduced.

Therefore, in the light-emitting display device 1100 according to another example embodiment of the present disclosure, the design of the gate driver GD can be flexibly changed depending on a mode of each active area AA. For example, according to an embodiment, only the second active area AA2 among the first active area AA1 and the second active area AA2 can operate in any one of the share viewing mode and the private viewing mode while the first active area AA1 can only provide the share viewing mode. In this situation, only the first emission signal generator GDE1 and the second emission signal generator GDE2 further required to operate the second active area AA2 can be separately disposed in the lateral non-active area NA adjacent to the second active area AA2 instead of the bezel area BA. Thus, the design regularity of the gate driver GD in the bezel area BA and the active area AA can be secured, and space and resources can be conserved.

The example embodiments of the present disclosure can also be described as follows:

According to an aspect of the present disclosure, the light-emitting display device includes a display panel in which an active area including a first active area and a second active area, and a non-active area adjacent to the active area are defined. Also, the light-emitting display device includes a plurality of sub-pixels disposed in the active area, and a gate driver disposed on the non-active area. Each of the plurality of sub-pixels includes a first light-emitting diode (LED) that emits light in response to a driving current and a first lens that refracts the light emitted from the first LED. Therefore, according to the present disclosure, the light-emitting display device can operate in various modes by using the lens to limit a viewing angle in each of the first and second active areas.

At least some of the plurality of sub-pixels can further include a second LED that emits light in response to the driving current; and a second lens that refracts the light emitted from the second LED and has a different shape than the first lens.

The first lens can be a half-cylindrical lens, and the second lens can be a half-spherical lens.

The second LED is disposed in all of the plurality of sub-pixels.

One of the active areas can operate independently in any one of a private viewing mode and a share viewing mode, and in the share viewing mode, the first LED can emit light, and the light emitted from the first LED can be output with a viewing angle that is limited by the first lens only in a first direction, and in the private viewing mode, the second LED can emit light, and the light emitted from the second LED can be output with a viewing angle that is limited by the second lens in both of the first direction and a second direction.

Each of the plurality of sub-pixels can further include a driving transistor configured to control the driving current; a first emission control transistor configured to be connected between the driving transistor and the first LED and transfers the driving current to the first LED; and a second emission control transistor configured to be connected between the driving transistor and the second LED and transfers the driving current to the second LED, and in the share viewing mode, the first emission control transistor can be turned on and the second emission control transistor can be turned off, and in the private viewing mode, the first emission control transistor is turned off and the second emission control transistor is turned on.

The light-emitting display device can further comprises a plurality of scan signal lines that extend in a row direction in the active area and transmit a scan signal to the plurality of sub-pixels; and a plurality of emission signal lines that extend in the row direction in the active area and transmit an emission signal to the plurality of sub-pixels, and the plurality of emission signal lines can include a first emission signal line that transmits a first emission signal to a gate electrode of the first emission control transistor; and a second emission signal line that transmits a second emission signal to a gate electrode of the second emission control transistor.

The first emission signal line can include a first-first emission signal line connected to the plurality of sub-pixels in the first active area; and a first-second emission signal line connected to the plurality of sub-pixels in the second active area, and the first-first emission signal line and the first-second emission signal line can be separated from each other.

The second emission signal line can include a second-first emission signal line connected to the plurality of sub-pixels in the first active area; and a second-second emission signal line connected to the plurality of sub-pixels in the second active area, and the second-first emission signal line and the second-second emission signal line can be separated from each other.

The gate driver can include a plurality of scan signal generators configured to output a scan signal, and a plurality of emission signal generators configured to output the emission signal.

The plurality of scan signal generators and the plurality of emission signal generators can be disposed in a part of the non-active area adjacent to one side of the first active area and the second active area.

The light-emitting display device can further comprise a plurality of scan signal auxiliary lines that extend in a column direction in the active area, and connect the plurality of scan signal lines to the plurality of scan signal generators; and a plurality of emission signal auxiliary lines that extend in the column direction in the active area and connect the plurality of emission signal lines to the plurality of emission signal generators.

A sub-pixel in the first active area among the plurality of sub-pixels includes only the first LED, and a sub-pixel in the second active area among the plurality of sub-pixels includes both the first LED and the second LED.

The first active area can operate in a share viewing mode, and the second active area operates in any one of a private viewing mode and the share viewing mode.

The light-emitting display device can further comprise a plurality of scan signal lines that extend in a row direction in the active area and transmit a scan signal to the plurality of sub-pixels; and a plurality of emission signal lines that extend in the row direction in the active area and transmit an emission signal to the plurality of sub-pixels, and the plurality of emission signal lines can include a first emission signal line that transmits a first emission signal to the sub-pixel in the second active area; and a second emission signal line that transmits a second emission signal to the sub-pixel in the second active area; and a third emission signal line that transmits a third emission signal to the sub-pixels in the first active area and the sub-pixel in the second active area.

The gate driver can include a plurality of scan signal generators configured to output a scan signal to the plurality of scan signal lines; a plurality of first emission signal generators configured to output the first emission signal; a plurality of second emission signal generators configured to output the second emission signal; and a plurality of third emission signal generators configured to output the third emission signal, and the plurality of scan signal generators and the plurality of third emission signal generators can be disposed in a part of the non-active area adjacent to one side of the first active area and the second active area, and the plurality of first emission signal generators and the plurality of second emission signal generators can be disposed in another part of the non-active area adjacent to another side of the second active area.

According to another aspect of the present disclosure, the light-emitting display device includes a display panel in which an active area including a first active area and a second active area, and a non-active area adjacent to the active area are defined. Also, the light-emitting display device includes a plurality of sub-pixels disposed in the active area, and a plurality of emission signal lines that extend in one direction in the active area and apply an emission signal to the plurality of sub-pixels. At least some of the plurality of emission signal lines are separated from each other at the boundary between the first active area and the second active area. Therefore, according to the present disclosure, it is possible to independently control each active area by separating the emission signal lines in the first active area from the emission signal lines in the second active area.

Each of the plurality of sub-pixels can include a first LED that emits light in a share viewing mode; a first emission control transistor configured to be turned on in response to the emission signal and transfers a driving current to the first LED; a second LED that emits light in a private viewing mode; and a second emission control transistor that can be turned on in response to the emission signal and transfers the driving current to the second LED, and the plurality of emission signal lines can include a first emission signal line configured to supply the emission signal to the first emission control transistor; and a second emission signal line configured to supply the emission signal to the second emission control transistor.

The first emission signal line can include a first-first emission signal line disposed in the first active area; and a first-second emission signal line disposed in the second active area and separated from the first-first emission signal line, and the second emission signal line can include a second-first emission signal line disposed in the first active area; and a second-second emission signal line disposed in the second active area and separated from the second-first emission signal line.

The light-emitting display device can further comprise a gate driver disposed in the non-active area, and the gate driver can include a plurality of first emission signal generators configured to output the emission signal to the first emission signal line; and a plurality of second emission signal generators configured to output the emission signal to the second emission signal line, and the first-first emission signal line and the first-second emission signal line are connected to different first emission signal generators from each other, among the plurality of first emission signal generators, and the second-first emission signal line and the second-second emission signal line are connected to different second emission signal generators from each other, among the plurality of second emission signal generators.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A light-emitting display device, comprising:
a display panel including an active area and a non-active area, the active area including a first active area and a second active area;
a plurality of sub-pixels disposed in the active area; and
a gate driver disposed in the non-active area,
wherein each of the plurality of sub-pixels includes:
a first light-emitting diode (LED) configured to emit light in response to a driving current; and
a first lens configured to refract the light emitted from the first LED.

2. The light-emitting display device according to claim 1, wherein at least some of the plurality of sub-pixels further include:
a second LED configured to emit light in response to the driving current; and
a second lens configured to refract the light emitted from the second LED,
wherein the second lens has a different shape than the first lens.

3. The light-emitting display device according to claim 2, wherein the first lens is a half-cylindrical lens, and
wherein the second lens is a half-spherical lens.

4. The light-emitting display device according to claim 2, wherein the active area includes a plurality of the second LEDs and each of the plurality of sub-pixels includes one of the plurality of second LEDs.

5. The light-emitting display device according to claim 4, wherein at least one of the first active area and the second active area is configured to operate independently in a private viewing mode and a share viewing mode,
wherein, in the share viewing mode, the first LED emits light, and the light emitted from the first LED is output with a viewing angle that is limited by the first lens only in a first direction, and
wherein, in the private viewing mode, the second LED emits light, and the light emitted from the second LED is output with a viewing angle limited by the second lens in the first direction and a second direction different than the first direction.

6. The light-emitting display device according to claim 5, wherein each of the plurality of sub-pixels further includes:
a driving transistor configured to control the driving current;
a first emission control transistor connected between the driving transistor and the first LED and configured to transfer the driving current to the first LED; and
a second emission control transistor connected between the driving transistor and the second LED and configured to transfer the driving current to the second LED,
wherein, in the share viewing mode, the first emission control transistor is turned on and the second emission control transistor is turned off, and
wherein, in the private viewing mode, the first emission control transistor is turned off and the second emission control transistor is turned on.

7. The light-emitting display device according to claim 6, further comprising:
a plurality of scan signal lines extending in a row direction in the active area and configured to transmit a scan signal to the plurality of sub-pixels; and
a plurality of emission signal lines extending in the row direction in the active area and configured to transmit an emission signal to the plurality of sub-pixels,
wherein the plurality of emission signal lines include:
a first emission signal line configured to transmit a first emission signal to a gate electrode of the first emission control transistor; and
a second emission signal line configured to transmit a second emission signal to a gate electrode of the second emission control transistor.

8. The light-emitting display device according to claim 7, wherein the first emission signal line includes:
a first-first emission signal line connected to a first-first group of sub-pixels among the plurality of sub-pixels in the first active area; and
a first-second emission signal line connected to a first-second group of sub-pixels among the plurality of sub-pixels in the second active area, and
wherein the first-first emission signal line and the first-second emission signal line are separated from each other.

9. The light-emitting display device according to claim 7, wherein the second emission signal line includes:
a second-first emission signal line connected to a second-first group of sub-pixels among the plurality of sub-pixels in the first active area; and
a second-second emission signal line connected to a second-second group of sub-pixels among the plurality of sub-pixels in the second active area, and
wherein the second-first emission signal line and the second-second emission signal line are separated from each other.

10. The light-emitting display device according to claim 9, wherein the gate driver includes:
a plurality of scan signal generators configured to output a scan signal, and
a plurality of emission signal generators configured to output the emission signal.

11. The light-emitting display device according to claim 10, wherein the plurality of scan signal generators and the plurality of emission signal generators are disposed in a part of the non-active area adjacent to a side of the first active area or a side of the second active area.

12. The light-emitting display device according to claim 11, further comprising:
a plurality of scan signal auxiliary lines extending in a column direction in the active area, and connecting the plurality of scan signal lines to the plurality of scan signal generators; and
a plurality of emission signal auxiliary lines extending in the column direction in the active area and connecting the plurality of emission signal lines to the plurality of emission signal generators.

13. The light-emitting display device according to claim 2, wherein the active area includes a plurality of first LEDs and a plurality of second LEDs,
wherein a sub-pixel in the first active area among the plurality of sub-pixels includes only one of the plurality of first LEDs and does not include any of the plurality of second LEDs, and
wherein a sub-pixel in the second active area among the plurality of sub-pixels includes one of the plurality of first LEDs and one of the plurality of second LEDs.

14. The light-emitting display device according to claim 13, wherein the first active area is configured to operate in a share viewing mode having a first viewing angle,
wherein the second active area is configured to operate in a private viewing mode having a second viewing angle and the share viewing mode, and
wherein the first viewing angle of the private viewing mode is smaller than the second viewing angle of the share viewing mode.

15. The light-emitting display device according to claim 13, further comprising:
a plurality of scan signal lines extending in a row direction in the active area and configured to transmit a scan signal to the plurality of sub-pixels; and
a plurality of emission signal lines extending in the row direction in the active area and configured to transmit an emission signal to the plurality of sub-pixels,
wherein the plurality of emission signal lines include:
a first emission signal line configured to transmit a first emission signal to a second sub-pixel among the plurality of sub-pixels in the second active area;
a second emission signal line configured to transmit a second emission signal to the second sub-pixel in the second active area; and
a third emission signal line configured to transmit a third emission signal to a first sub-pixel among the plurality of sub-pixels in the first active area and the second sub-pixel in the second active area,
wherein the third emission signal line is disposed in both of the first active area and the second active area, and
wherein the first emission signal line and the second emission signal line are both disposed in the second active area and are absent from the first active area.

16. The light-emitting display device according to claim 15, wherein the gate driver includes:
a plurality of scan signal generators configured to output a scan signal to the plurality of scan signal lines;
a plurality of first emission signal generators configured to output the first emission signal;
a plurality of second emission signal generators configured to output the second emission signal; and
a plurality of third emission signal generators configured to output the third emission signal,
wherein the plurality of scan signal generators and the plurality of third emission signal generators are disposed in a first part of the non-active area adjacent to a side of the first active area or a side of the second active area, and
wherein the plurality of first emission signal generators and the plurality of second emission signal generators are disposed in a second part of the non-active area adjacent to another side of the second active area.

17. A light-emitting display device, comprising:
a display panel including an active area and a non-active area, the active area including a first active area and a second active area;
a plurality of sub-pixels disposed in the active area; and
a plurality of emission signal lines that extend in one direction in the active area and are configured to apply an emission signal to the plurality of sub-pixels,
wherein at least some of the plurality of emission signal lines are separated from each from each other at a boundary between the first active area and the second active area.

18. The light-emitting display device according to claim 17, wherein each of the plurality of sub-pixels includes:
a first light-emitting diode (LED) configured to emit light in a share viewing mode;
a first emission control transistor configured to be turned on in response to one of the emission signals and transfer a driving current to the first LED;
a second LED configured to emit light in a private viewing mode; and
a second emission control transistor configured to be turned on in response to the emission signal and transfer the driving current to the second LED,
wherein the plurality of emission signal lines include:
a first emission signal line configured to supply the emission signal to the first emission control transistor; and
a second emission signal line configured to supply the emission signal to the second emission control transistor.

19. The light-emitting display device according to claim 18, wherein the first emission signal line includes:
a first-first emission signal line disposed in the first active area; and
a first-second emission signal line disposed in the second active area, the first-first emission signal line being separated from the first-first emission signal line, and
wherein the second emission signal line includes:
a second-first emission signal line disposed in the first active area; and
a second-second emission signal line disposed in the second active area, the second-second emission signal line being separated from the second-first emission signal line.

20. The light-emitting display device according to claim 19, further comprising:
a gate driver disposed in the non-active area,
wherein the gate driver includes:
a plurality of first emission signal generators configured to output the emission signal to the first emission signal line; and
a plurality of second emission signal generators configured to output the emission signal to the second emission signal line,
wherein the first-first emission signal line and the first-second emission signal line are connected to different first emission signal generators among the plurality of first emission signal generators, and
wherein the second-first emission signal line and the second-second emission signal line are connected to different second emission signal generators among the plurality of second emission signal generators.
